(19) United States
(12) Patent Application Publication
(10) Pub. No.: US 2022/0164510 A1
(43) Pub. Date: May 26, 2022

(54) AUTOMATED DESIGN OF FIELD PROGRAMMABLE GATE ARRAY OR OTHER LOGIC DEVICE BASED ON ARTIFICIAL INTELLIGENCE AND VECTORIZATION OF BEHAVIORAL SOURCE CODE

(71) Applicant: Raytheon Company, Waltham, MA (US)

(72) Inventors: Stephen R. Reid, Ayer, MA (US); Sandeep Dutta, Foster City, CA (US)

(21) Appl. No.: 17/364,565

(22) Filed: Jun. 30, 2021

Related U.S. Application Data
(60) Provisional application No. 63/117,979, filed on Nov. 24, 2020.
(60) Provisional application No. 63/117,988, filed on Nov. 24, 2020.
(60) Provisional application No. 63/117,998, filed on Nov. 24, 2020.

(51) Int. Cl. G06F 30/343

(52) U.S. Cl. CPC G06F 30/343

(57) ABSTRACT

A method includes obtaining behavioral source code defining logic to be performed using at least one logic device, hardware information associated with the at least one logic device, and constraints identifying user requirements associated with the at least one logic device. The method also includes generating a design for the at least one logic device using the behavioral source code, the hardware information, and the constraints. The design enables the at least one logic device to execute the logic while satisfying the user requirements. The design is generated using a machine learning/artificial intelligence (ML/AI) algorithm that iteratively modifies potential designs to meet the user requirements.

### CROSS-REFERENCE TO RELATED APPLICATIONS AND PRIORITY CLAIM

This application claims priority under 35 U.S.C. § 119(e) to U.S. Provisional Patent Application Nos. 63/117,979; 63/117,988; and 63/117,998 filed on Nov. 24, 2020,

all of which are hereby incorporated by reference in their entirety.

This application is related to the following non-provisional patent applications being filed concurrently herewith:
a U.S. non-provisional patent application filed under docket number 20-14473-US-NP (RAYN01-14473) and entitled “AUTOMATED DESIGN OF BEHAVIORAL-BASED DATA MOVERS FOR FIELD PROGRAMMABLE GATE ARRAYS OR OTHER LOGIC DEVICES”; and
a U.S. non-provisional patent application filed under docket number 20-14479-US-NP (RAYN01-14479) and entitled “RUN-TIME SCHEDULERS FOR FIELD PROGRAMMABLE GATE ARRAYS OR OTHER LOGIC DEVICES”.
   Both of these non-provisional applications are hereby incorporated by reference in their entirety.

### GOVERNMENT RIGHTS

This invention was made with government support under contract number FA8650-19-C-7975 awarded by the United States Air Force. The government has certain rights in the invention.

### TECHNICAL FIELD

This disclosure relates generally to the design of field programmable gate arrays (FPGAs) and other logic devices. More specifically, this disclosure relates to the automated design of a field programmable gate array or other logic device based on artificial intelligence and vectorization of behavioral source code.

### BACKGROUND

The design of a logic device, such as a field programmable gate array (FPGA), has a direct impact on how effectively the logic device can operate. Unfortunately, designing an FPGA or other logic device is often a complex task performed by one or more subject matter experts who have detailed knowledge about the specific FPGA platform or other logic device platform in which a design is being implemented. This design process can take a prolonged period of time, and it is often difficult to generate a design for an FPGA or other logic device that satisfies various design criteria.

### SUMMARY

This disclosure provides automated design of a field programmable gate array or other logic device based on artificial intelligence and vectorization of behavioral source code.

In a first embodiment, a method includes obtaining behavioral source code defining logic to be performed using at least one logic device, hardware information associated with the at least one logic device, and constraints identifying user requirements associated with the at least one logic device. The method also includes generating a design for the at least one logic device using the behavioral source code, the hardware information, and the constraints. The design enables the at least one logic device to execute the logic while satisfying the user requirements. The design is generated using a machine learning/artificial intelligence (ML/AI) algorithm that iteratively modifies potential designs to meet the user requirements.

In a second embodiment, an apparatus includes at least one processor configured to obtain behavioral source code defining logic to be performed using at least one logic device, hardware information associated with the at least one logic device, and constraints identifying user requirements associated with the at least one logic device. The at least one processor is also configured to generate a design for the at least one logic device using the behavioral source code, the hardware information, and the constraints such that the design enables the at least one logic device to execute the logic while satisfying the user requirements. To generate the design for the at least one logic device, the at least one processor is configured to use an ML/AI algorithm that is configured to iteratively modify potential designs to meet the user requirements.

In a third embodiment, a non-transitory computer readable medium contains instructions that when executed cause at least one processor to obtain behavioral source code defining logic to be performed using at least one logic device, hardware information associated with the at least one logic device, and constraints identifying user requirements associated with the at least one logic device. The medium also contains instructions that when executed cause the at least one processor to generate a design for the at least one logic device using the behavioral source code, the hardware information, and the constraints, the design enabling the at least one logic device to execute the logic while satisfying the user requirements. The instructions that when executed cause the at least one processor to generate the design for the at least one logic device include instructions that when executed cause the at least one processor to use an ML/AI algorithm that is configured to iteratively modify potential designs to meet the user requirements.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example system containing logic devices according to this disclosure;

FIG. 2 illustrates an example architecture supporting automated design of logic devices according to this disclosure;

FIG. 3 illustrates an example identification of design parameters for logic devices during automated design according to this disclosure;

FIG. 4 illustrates an example iterative process for identifying design parameters for logic devices during automated design according to this disclosure;

FIG. 5 illustrates an example process for modifying design parameters for logic devices during automated design according to this disclosure;

FIG. 6 illustrates an example summarized process for usage of an ontology during automated design of logic devices according to this disclosure;

FIG. 7 illustrates an example technique for vectorizing behavioral source code for use during automated design of logic devices according to this disclosure;

FIG. 8 illustrates an example technique for modifying behavioral source code prior to vectorization for use during automated design of logic devices according to this disclosure;

FIG. 9 illustrates an example computing device or system supporting automated design of logic devices according to this disclosure; and

FIG. 10 illustrates an example method for automated design of logic devices according to this disclosure.

### DETAILED DESCRIPTION

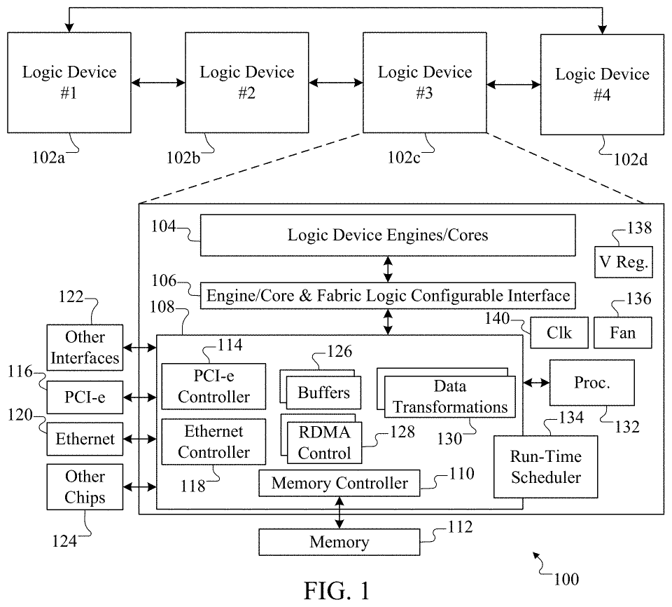

FIGS. 1 through 10, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As described above, the design of a logic device, such as a field programmable gate array (FPGA), has a direct impact on how effectively the logic device can operate. Unfortunately, designing an FPGA or other logic device is often a complex task performed by one or more subject matter experts who have detailed knowledge about the specific FPGA platform or other logic device platform in which a design is being implemented. This design process can take a prolonged period of time, and it is often difficult to generate a design for an FPGA or other logic device that satisfies various design criteria.

This disclosure describes a logic device design automation tool based on an artificial intelligence (AI)/machine learning (ML) approach, which can allow for a reduced or minimized use of subject matter experts (SMEs) when designing FPGAs or other logic devices. As described in more detail below, the AI/ML approach allows the logic device design automation tool to create logic device design solutions and intelligently iterate on additional design solutions as needed to satisfy user-provided behavioral requirements for FPGAs or other logic devices. For example, the logic device design automation tool can be used to design FPGAs or other logic devices while satisfying available chip resources, power, temperature, clock frequency, latency, or other user requirements. Among other things, this can be accomplished using knowledge of how prior changes to logic device designs affected these types of user requirements. This can help to guide the automated design process and focus the automated design process on making design changes using solution methods that are more likely to result in improved designs.

Various benefits or advantages may be obtained using the logic device design automation tool depending on the implementation. For example, the logic device design automation tool can support rapid development of FPGA designs or other logic device designs with reduced costs, defects, and development times. This also enables fast simulation times and improves re-use through behavioral development. A weighted AI/ML approach can be used to allow estimated effects of each solution method and feedback for higher accuracy. A deep knowledge expert system, an ontology database, and an AI/ML algorithm can be used to support the logic device design automation tool, and they may allow users to add to solution methods without tool changes. Additional details of example embodiments of the logic device design automation tool are provided below.

In some cases, a low-level virtual machine (LLVM) automation tool may be used to support the operations of the logic device design automation tool. The LLVM automation tool takes behavioral source code and generates vectorized code for execution by processing engines or cores in logic devices. For example, the LLVM automation tool can target one or more processing engines or cores to create efficient sources for vectorizing onto the engine(s) or core(s) in order to minimize application latency. While LLVM is commonly used to compile to many different target platforms (such as various central processing units or graphics processing units), it does not have support for use in logic devices such as FPGAs. Also, the LLVM automation tool may utilize a library of functional blocks based on the lowest latency and the most efficient methods of implementation from behavioral source code. For example, a user may provide a level of bit accuracy required or desired, and the LLVM automation tool can select different vectorized implementations or algorithms that minimize latency based on the provided bit accuracy. LLVM typically involves the use of an auto-vectorizer that creates intermediate code, which is converted into a suitable language for a logic device's processing engines or cores. Experimentation can be performed for many source code algorithms and mathematical operations to create a highly-tuned library that is used to generate the vectorized source code for processing engines or cores.

Various benefits or advantages may be obtained using the LLVM automation tool depending on the implementation. For example, the LLVM automation tool supports rapid development, reduces defects, and improves re-use through the use of C, C++, or other behavioral source code (instead of code for a specific target technology). Also, the LLVM automation tool may allow for the automatic use of the lowest latencies and the most efficient methods without requiring subject matter knowledge of target technologies or their associated languages. This also reduces defects, and behavioral source development enables re-use to many programs. Additional details of example embodiments of the LLVM automation tool are provided below.

In addition, in some cases, pre-LLVM automation can be performed to modify behavioral source code in preparation for conversion to vectorized code in order to support the LLVM automation tool. Without this automation, a user may have to parallelize code and identify data movements for each application to all processing engines or cores of a logic device. A pre-LLVM automation tool takes behavioral source code and outputs new behavioral source code that allow the LLVM automation tool to be run for one or more processing engines or cores. The parallelization may best determine how an application can be decomposed onto many engines or cores while minimizing data movement overhead, power, and latency. Additional details of example embodiments of the pre-LLVM automation tool are provided below.

FIG. 1 illustrates an example system 100 containing logic devices 102a-102d according to this disclosure. As shown in FIG. 1, the system 100 includes four logic devices 102a-102d that are arranged in a ring configuration, meaning each logic device 102a-102d is coupled to two neighboring logic devices 102a-102d using a loop or circular set of connections. However, the number of logic devices and the arrangement of the logic devices are for illustration only. The system 100 may include any other suitable number of logic devices, possibly including a single logic device. Also, the system 100 may include any other suitable connections between logic devices (assuming multiple logic devices are present).

Each of the logic devices 102a-102d represents a programmable semiconductor chip or other integrated circuit that can be programmed to perform one or more desired functions. For example, each of the logic devices 102a-102d may represent a field programmable gate array (FPGA), an adaptive compute accelerator platform (ACAP), an application-specific integrated circuit (ASIC), a very-large-scale integration (VSLI) chip, a memory chip, a data converter, a central processing unit (CPU), an accelerator chip, or other semiconductor chip or other integrated circuit containing one or more programmable resources.

In this example, each of the logic devices 102a-102d includes a collection of logic device engines or cores 104, which represent processing circuitry or other components that can be programmed to perform one or more desired functions. For instance, the engines or cores 104 may represent programmable processing cores, programmable artificial intelligence (AI) engines, or other programmable processing circuitry. Each of the logic devices 102a-102d may include any suitable number of processing engines or cores 104. In some cases, for example, each logic device 102a-102d may include several hundred or more of the engines or cores 104. The number of engines or cores 104 may depend, among other things, on the intended application for the logic device 102a-102d, the physical size of the logic device 102a-102d, and the physical size of each engine or core 104.

An engine/core and fabric logic configurable interface 106 represents a physical interface to the various engines or cores 104 of the logic device 102a-102d. For example, the interface 106 may include a fabric or other configurable set of communication pathways that allow data, instructions, or other information to be provided from one or more sources to the engines or cores 104 and that allow data or other information to be received from the engines or cores 104 and provided to one or more destinations. The fabric or other reconfigurable communication pathways can also support communications between various ones of the engines or cores 104. The interface 106 includes any suitable structure configured to provide a physical interface with and communications to, from, and between processing engines or cores of a logic device.

Various data movement components 108 are provided in each logic device 102a-102d to support the movement of instructions and data within or through the logic device 102a-102d. This can include instruction and data transfers involving the engines or cores 104 via the interface 106. For example, the data movement components 108 may include at least one memory controller 110, which can support interactions and information exchanges involving at least one external memory 112. Each external memory 112 represents any suitable storage and retrieval device or devices, such as one or more Double Data Rate-4 (DDR4) memory devices, Low-Power Double Data Rate-4 (LPDDR4) memory devices, or other suitable memory devices. Each memory controller 110 may therefore represent a DDR memory controller, LPDDR4 memory controller, or other suitable memory controller configured to facilitate storage of information in and retrieval of information from the at least one external memory 112.

The data movement components 108 may optionally include one or more interfaces that facilitate communications over one or more external pathways. For instance, a peripheral component interconnect express (PCI-e) controller 114 may be used to support communications over a PCI-e bus 116, and an Ethernet controller 118 may be used to support communications over an Ethernet, gigabit Ethernet, ten gigabit Ethernet, or other Ethernet connection 120. Communications over one or more other suitable interfaces 122 may also be supported by the data movement components 108, and communications with other chips 124 (meaning other logic devices 102a-102d) may be supported.

The data movement components 108 may further include one or more buffers 126 (such as one or more fabric memories) that can be used to temporarily store information being transported within or through the logic device 102a-102d. Each buffer 126 may, for instance, represent a block random access memory (BRAM) or a unified random access memory (URAM). One or more remote direct memory access (RDMA) controllers 128 facilitate data transfers involving the logic device 102a-102d. For example, the one or more RDMA controllers 128 may facilitate data transfers to or from the logic device 102a-102d involving one or more of the memory/memories 112, bus 116, connection 120, or other interfaces 122. The one or more RDMA controllers 128 here can also be used to provide flow control for the data transfers. Note that the ability to support data transfers using the one or more RDMA controllers 128 allows the data transfers to occur without using much if any logic device processing resources. This may also allow large numbers of data transfers to occur in parallel, which helps to achieve high throughputs. In addition, one or more data transformations 130 may be applied to data being moved within or through the logic device 102a-102d. This may allow, for example, row or column transpose operations or other operations to occur on data being transported within or through the logic device 102a-102d.

It should be noted here that various buffers 126, RDMA controllers 128, and data transformations 130 may be used in various ways to support desired data flows involving the logic device 102a-102d. Thus, for example, a first data flow may involve a first RDMA controller 128, a second data flow may involve a second RDMA controller 128 and a first buffer 126, and a third data flow may involve a third RDMA controller 128, a second buffer 126, and a fourth RDMA controller 128. As a result, various combinations of buffers, RDMA controllers, data transformations, and other data movement components 108 may be used in the logic devices 102a-102d. In general, the data movement components 108 may be designed or configured to support various flows of data within or through each logic device 102a-102d as needed or desired.

Each logic device 102a-102d here optionally includes at least one embedded processing device 132, which can execute various instructions to provide desired functionality in the logic device 102a-102d. For instance, the embedded processing device 132 may generate data that is provided to the engines or cores 104 or process data that is received from the engines or cores 104. The embedded processing device 132 may also interact with other logic devices 102a-102d. The embedded processing device 132 represents any suitable processing device configured to execute instructions, such as an embedded real-time (RT) processor or an embedded ARM processor or other reduced instruction set computing (RISC) processor.

Each logic device 102a-102d here includes or supports a run-time scheduler 134, which handles the scheduling of application or other logic execution by the processing engines or cores 104 and possibly other components of the logic device 102a-102d. For example, the run-time scheduler 134 may use a combination of events, operating modes, thermal information, or other information (at least some of which is not or cannot be known at compile time) to intelligently decide how best to schedule various applications or other logic to be executed by the engines or cores 104. The run-time scheduler 134 can also consider latency information and power requirements of the engines or cores 104 when determining how to schedule execution of the applications or other logic. If execution cannot be performed in a desired manner (such as when an application or other logic cannot be executed within a desired time period), the run-time scheduler 134 of one logic device 102a-102d may communicate with other logic devices 102a-102d in order to determine if the application or other logic can be suitably executed by another logic device 102a-102d.

Overall, the run-time scheduler 134 here can support a number of operations associated with execution scheduling for one or more applications or other logic. For example, the run-time scheduler 134 can support run-time application switching, meaning the applications or other logic executed by the engines or cores 104 of each logic device 102a-102d can change over time during operation of the logic devices 102a-102d. As another example, the run-time scheduler 134 can move an application or other logic executed by a first logic device 102a-102d to a second logic device 102a-102d, such as due to the current or predicted future thermal or processing load associated with the first logic device 102a-102d. As yet another example, the run-time scheduler 134 can reload instructions and application data in one or more of the engines or cores 104 while an application or other logic is running, which may support features such as extremely fast application switching. As still another example, the run-time scheduler 134 can support partial reconfiguration of one or more resources that are common to more than one application or other logic, so the run-time scheduler 134 can configure the one or more resources in advance of scheduling run-time needs. The run-time scheduler 134 interfaces with the various data movers to provide concurrent control and data movement within and between the logic devices 102a-102d.

Note that as part of its scheduling functionality, the run-time scheduler 134 can perform or initiate automatic instruction and data movements to support the dynamic execution of the applications or other logic by the engines or cores 104. In this way, the instructions and data needed for dynamic execution of applications or other logic can be provided to the engines or cores 104, such as via the interface 106 and one or more of the data movement components 108. Moreover, the run-time scheduler 134 can support inter-chip instruction and data movements if needed. This means that the run-time scheduler 134 in one logic device 102a-102d can provide instructions and data needed for execution of an application or other logic to another logic device 102a-102d, thereby allowing the other logic device 102a-102d to execute the instructions and use the data. The decision to move execution of an application or other logic can be made at run-time.

This type of functionality may find use in a number of potential applications. For example, various high-speed real-time sensor systems and other systems may typically involve the use of specialized compute accelerators. As a particular example, various radar systems may use specialized hardware components to process return signals. The engines or cores 104 of one or more logic devices 102a-102d can be used to provide the functionality of these specialized compute accelerators. Moreover, the run-time scheduler 134 can schedule the execution of one or more applications or other logic to provide the desired functionality and move the application(s) or other logic among the engines or cores 104 of one or more logic devices 102a-102d using the data movement components 108 as needed to achieve the desired processing. In some cases, this can reduce the number of logic devices and other hardware in a system. This is because one or more logic device engines or cores 104 and the logic devices 102a-102d themselves can be quickly programmed and reprogrammed as needed or desired during run-time, which helps to improve the CSWAP of the overall system.

Each logic device 102a-102d may include a number of additional components or features as needed or desired. For example, one or more fans 136 may be used for the logic device 102a-102d to cool the engines or cores 104 or other components of the logic device 102a-102d. As another example, one or more voltage regulators 138 may be used to produce operating voltages for one or more components of the logic device 102a-102d. At least one clock 140 may represent an oscillator or other source of at least one clock signal, which can be used to control the frequency, power, and resulting latency of various operations of the logic device 102a-102d.

As described in more detail below, a logic device design automation tool based on an AI/ML approach may be used to create designs for various aspects of the logic devices 102a-102d, such as designs for executing applications using the engines or cores 104 and other components of the logic devices 102a-102d. The AI/ML approach can be used to identify design solutions and iteratively generate additional design solutions to satisfy user-provided behavioral requirements for the logic devices 102a-102d. Techniques for designing other components of the logic devices 102a-102d, such as the data movement components 108 and the run-time scheduler 134, are described below and in the related non-provisional patent applications incorporated by reference above. In some cases, an LLVM automation tool may also be used to generate vectorized code from behavioral source code for execution by the engines or cores 104 of the logic devices 102a-102d. Optionally, a pre-LLVM automation tool may process the behavioral source code and output new behavioral source code for the LLVM automation tool to process.

Although FIG. 1 illustrates one example of a system 100 containing logic devices 102a-102d, various changes may be made to FIG. 1. For example, various components in FIG. 1 may be combined, further subdivided, replicated, omitted, or rearranged and additional components may be added according to particular needs. Also, FIG. 1 illustrates one example type of system in which at least one logic device may be designed using an automation tool. However, logic devices designed using an automation tool may be used in any other suitable system.

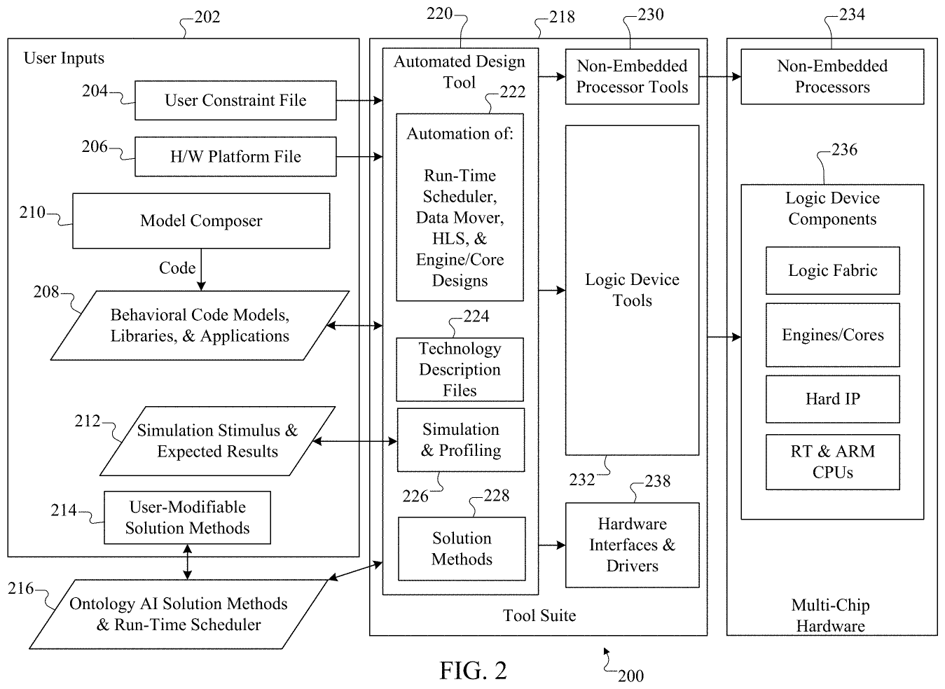

FIG. 2 illustrates an example architecture 200 supporting automated design of logic devices according to this disclosure. For ease of explanation, the architecture 200 is described as being used to design one or more logic devices 102a-102d in the system 100 of FIG. 1 above. However, the architecture 200 may be used to design any other suitable logic device(s), and the logic device(s) may be used in any suitable system(s).

As shown in FIG. 2, the architecture 200 obtains a number of user inputs 202. In this example, the user inputs 202 include at least one user constraint file 204. The user constraint file 204 can identify various user-defined constraints to be placed on a logic device 102a-102d. The constraints define permitted characteristics of the design of the logic device 102a-102d. For example, the user constraint file 204 can identify the external interfaces, latency, resource limits, power, and clock frequency (which defines a clock period for timing closure) for each application to be executed by the logic device 102a-102d. For the resource limits, the user constraint file 204 can also specify whether multiple applications can operate or be executed simultaneously or share resources of the logic device 102a-102d. The user constraint file 204 may also specify the priority of requirements to be solved during the design of the logic device 102a-102d. This may allow, for example, higher-priority requirements to be solved or optimized during the design of the logic device 102a-102d, even if lower-priority requirements cannot be satisfied during the design of the logic device 102a-102d. The user constraint file 204 may be received from any suitable source(s), such as from one or more users.

The user inputs 202 also include at least one hardware platform file 206. The hardware platform file 206 includes or represents various information about the hardware actually contained in the logic devices 102a-102d and boards or other larger structures that contain additional components and interfaces (such as the resources 112a-112b, 116, 120 and other logic devices). For example, the hardware platform file 206 may identify the numbers and types of engines or cores 104, engine/core and fabric logic configurable interface 106, and external interface(s) supported by the logic device 102a-102d. Various characteristics of the hardware in the logic device 102 can also be identified, such as the speed/latencies of the engines or cores 104, the ways in which the engine/core and fabric logic configurable interface 106 can be configured, and the bandwidths/speeds of the external interfaces.

The user inputs 202 further include behavioral source models, libraries, and applications 208, which can define the actual logic to be executed by the engines or cores 104 of the logic device 102 during use. This can include, for example, radar functionality to be executed in a radar application, sensor analysis functionality to be executed in an autonomous vehicle application, or other functionality to be executed in other applications. In some cases, at least some of the behavioral source models, libraries, and applications 208 may be manually created by a user. In other cases, a model composer 210 may receive inputs from a user defining a behavioral source code model to be implemented, and the model composer 210 may automatically generate at least part of the behavioral source models, libraries, and applications 208. The model composer 210 may, for instance, represent a MATLAB, SEVIULINK, or XILINX tool for converting source code models into actual source code. The behavioral source models, libraries, and applications 208 generally represent one or more applications to be automatically mapped to chip resources, such as the engines or cores 104, of the logic device 102a-102d. Since the logic device 102a-102d may be used in a wide range of applications, the behavioral source models, libraries, and applications 208 to be used may vary widely based on the intended application.

The user inputs 202 may further include simulation information 212 and user-modifiable solution method information 214. The simulation information 212 may include stimuli for simulations to be performed using a logic device design and expected results associated with the stimuli. The user-modifiable solution method information 214 represents an automation tool-provided list of methods that can be employed by the automation tool to solve a user's requirements for latency, resources, power, and timing closure. An additional input here represents ontology-based information 216, which can include AI-based information regarding the potential design for the logic device 102. The ontology-based information 216 may include or represent information associated with an ML/AI-based deep knowledge expert system, which can be used to capture and use information for mapping user applications to logic device designs while satisfying user constraints.

A tool suite 218 receives the various inputs and processes the information to automatically create a possible design for a logic device 102a-102d. The tool suite 218 can thereby help to reduce defects and improve design times for FPGAs or other types of logic devices 102a-102d. The tool suite 218 represents any suitable software automation tool for designing logic devices. In this example, the tool suite 218 includes an automated design tool 220, which can be used to support various functions for automating the design of specific components of the logic device 102a-102d. This functionality includes a design function 222 for automating run-time scheduler, data mover, High-Level Synthesis (HLS), and engine/core designs of a logic device 102a-102d. This functionality also supports the use of one or more technology description files 224, which can describe the logic device 102a-102d being designed (which has the benefit of minimizing modifications required for the automated design tool 220 for each new target technology). This functionality further includes a simulation and profiling function 226, which can simulate the operation of the designed logic device 102a-102d and compare the simulated results with expected results or debug or profile the simulated results. In addition, this functionality supports the consideration of various solution methods 228, including those defined in the user-modifiable solution method information 214 and ontology-based solution methods identified by the automation tool. The automated design tool 220 represents any suitable software tool for designing various aspects of logic devices, such as the VISUAL SYSTEM INTEGRATOR (VSI) software tool from SYSTEM VIEW, INC. (as modified to support the design of logic devices in accordance with this disclosure).

At least some of the outputs from the automated design tool 220 may be processed by one or more additional tools 230, 232. For example, the tool 230 may be used to convert any suitable aspects of the design of a logic device 102a-102d (as determined by the automated design tool 220) into compiled code or other logic that may be executed by one or more non-embedded processors 234 associated with the hardware platform file 206. The tool 232 may be used to convert any suitable aspects of the design of the logic device 102a-102d (as determined by the automated design tool 220) into compiled code, chip build (such as an FPGA configuration file), or other logic that may be executed by one or more components 236 of the logic device 102a-102d, such as code that can be used with a fabric (interface 106), engines/cores 104, hard intellectual property (IP) modules, or embedded processing devices 132 of the logic device 102a-102d. The tool(s) 230, 232 that are used here can vary depending on the logic device 102a-102d ultimately being designed. For instance, the tools 232 may include FPGA company-specific tools, such as the XILINX VIVADO tool, the XILINX VITIS tool, or a XILINX AIE or network-on-a-chip (NoC) compiler. In addition, the outputs from the automated design tool 220 may include a definition of one or more hardware interface and one or more drivers 238 that can be used to interact with the logic device 102a-102d as designed.

The automated design tool 220 can use various approaches described below to support the generation of a design for logic devices 102a-102d. This includes analyzing the various user inputs 202 to determine how one or more applications can be executed using the engines or cores 104 or other components of the logic device(s) 102a-102d while satisfying the user's constraints. This may also include vectorizing behavioral source code to be executed using the engines or cores 104 of the logic device(s) 102a-102d and optionally pre-processing the behavioral source code to support the vectorization.

Although FIG. 2 illustrates one example of an architecture 200 supporting automated design of logic devices 102a-102d, various changes may be made to FIG. 2. For example, various components in FIG. 2 may be combined, further subdivided, replicated, omitted, or rearranged and additional components may be added according to particular needs. Also, the actual technique for designing one or more logic devices 102a-102d can easily vary based on, among other things, the specific logic device 102a-102d being designed. In addition, one or more logic devices 102a-102d may be designed using any other suitable automation tool. As a result, while the designing of one or more logic devices 102a-102d is described above as being part of a larger collection of tools or other applications/logic that support partial- or fully-automated designing of logic devices, the approaches for designing one or more logic devices 102a-102d described in this patent document may be used individually or with any other suitable collection of tools or other applications/logic that support partial- or fully-automated designing of logic devices.

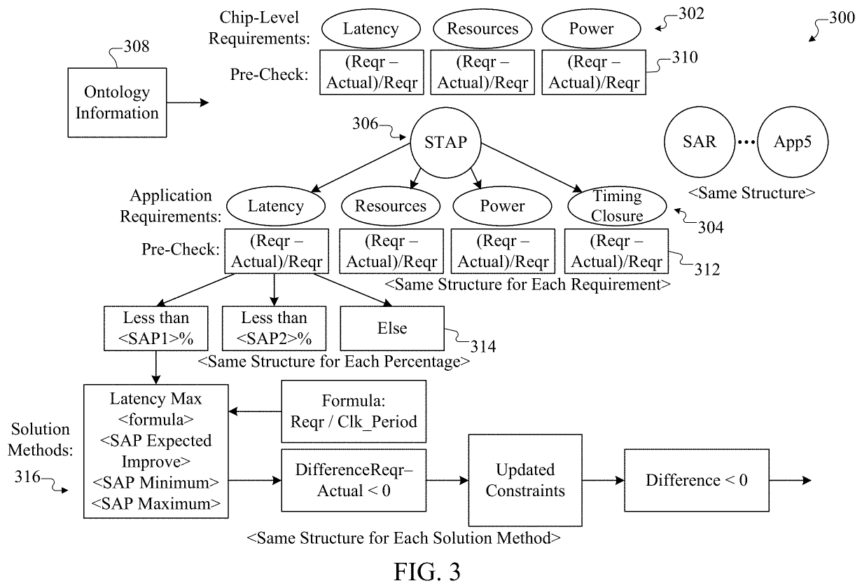

FIG. 3 illustrates an example identification 300 of design parameters for logic devices during automated design according to this disclosure. More specifically, FIG. 3 illustrates example requirements for logic devices that may be considered and example ways in which design parameters may be adjusted to satisfy those requirements during automated design of logic devices. For ease of explanation, the identification 300 of design parameters is described as being performed by the architecture 200 of FIG. 2 to design one or more logic devices 102a-102d in the system 100 of FIG. 1 above. However, the identification 300 of design parameters may be performed using any other suitable architecture to design any other suitable logic device(s), and the logic device(s) may be used in any suitable system(s).

As shown in FIG. 3, there are various chip-level requirements 302 associated with each logic device 102a-102d, and there are various application-level requirements 304 associated with each application 306 to be executed by the logic device 102a-102d. In this example, the chip-level requirements 302 include latency, resource, and power requirements, and the application-level requirements 304 include latency, resource, power, and timing closure requirements. The latency requirements generally identify the maximum latency permitted for the logic device 102a-102d as a whole and for each application 306 to be executed by the logic device 102a-102d. The resource requirements generally identify the maximum resources permitted to be used by the logic device 102a-102d as a whole and by each application 306 to be executed by the logic device 102a-102d (including whether one or multiple applications 306 can be executed at any given time). The power and temperature limit requirements generally identify the maximum power permitted to be used by the logic device 102a-102d as a whole and by each application 306 to be executed by the logic device 102a-102d. The timing closure requirements generally identify the clock frequencies permitted to be used by each application 306 to be executed by the logic device 102a-102d.

Among other things, the automated design tool 220 operates to identify how the applications 306 can be executed by the engines or cores 104 or other components of the logic device 102a-102d while satisfying as many of these requirements 302, 304 as possible. If a design that satisfies all of these requirements 302, 304 cannot be identified, priorities defined in the user constraint file 204 can be used to identify those requirements 302, 304 that are more or less important in terms of being satisfied during the design process. Ideally, however, the automated design tool 220 can be used to solve all requirements 302, 304 for each individual application 306 to be executed and for all applications 306 to be executed simultaneously while satisfying all chip-level constraints.

In this example, ontology information 308 is also received for use by the automated design tool 220. The ontology information 308 generally represents information from an ontology database, such as a database that provides the ontology-based information 216 described above. In some cases, at least some of the requirements 304 may be defined in the user constraint file 204, and at least some of the requirements 302 may be defined in the ontology information 308. For example, the ontology information 308 may specify the overhead of latency, resource, and power requirements that are not included in application kernels. The ontology information 308 may also identify the times needed to re-use identical logic device resources, such as the times needed to re-use engines or cores 104 of the logic device 102a-102d during application switching (including all times needed for embedded processor instruction re-load, engine/core instruction re-load, or partial reconfiguration).

In this example, the requirements 304 can be identified for each application 306 to be executed by the logic device 102a-102d being designed. In this particular example, the applications 306 include a space-time adaptive processing (STAP) algorithm, a synthetic aperture radar (SAR) algorithm, and a number of additional algorithms. However, these specific algorithms and the number of algorithms are for illustration only and can vary depending on the specific use of the logic device 102a-102d.

After an initial design for a logic device 102a-102d is determined by the automated design tool 220, pre-checks 310 and 312 are performed in order to identify whether the various requirements 302, 304 are satisfied by the design. The initial design may be determined in any suitable manner, such as based on an initial assignment of applications to engines or cores 104 or other hardware resources of the logic device 102a-102d. In some cases, the initial assignment may be based on user input. In other cases, the initial assignment may be based on the ontology information 308 or other information, such as when the initial assignment represents a first “best guess” assignment of applications to hardware resources. Each pre-check 310, 312 here takes the form of a percentage defined by the value of a design characteristic's requirement (such as a latency, resource, power, or timing closure requirement 302 or 304) minus the actual value of the characteristic (such as an actual latency, resource, power, or timing closure) divided by the value of the characteristic's requirement. Note, however, that prechecks in other forms may be used here. Depending on the results of the pre-check 310, 312, one of multiple mitigations can be applied to try and improve the design of the logic device 102a-102d.

The example approach used by the automated design tool 220 in FIG. 3 supports case-based decision theory (CBDT) problem solving, which can take the form of a semantic graph. If metrics collected for an individual application 306 do not satisfy that individual application's requirements 304 or if metrics collected for a set of applications 306 do not satisfy the chip-level requirements 302, various “solution methods” are available to improve the design of the logic device 102a-102d (ideally to cause the metrics to satisfy the appropriate requirements 302, 304). Prediction measures can be used for each solution method that might be applied to the design in order to improve the design and satisfy the appropriate requirements 302, 304. The semantic graph may contain requirements, actual results, solution types (physical), and data values (logical) that can be used to achieve a design solution that solves all requirements 302, 304 at once.

In FIG. 3, this is represented using different branches 314, where the different branches 314 are associated with different percentage thresholds. While only three branches 314 associated with two percentage thresholds and one “else” condition are shown here, any number of branches 314 may be used. The percentage thresholds may be referred to as “site application parameters” or “SAPs” below. Each branch 314 is associated with one or more solution methods 316. Each solution method 316 defines a technique or approach for modifying one or more design parameters of the logic device 102a-102d that might achieve an improvement in the associated requirement 304 for an application 306 (or in the associated requirement 302, which can be based on the requirement 304 associated with the solution method 316). In this way, the semantic graph essentially provides nodes for each requirement 304 associated with an application 306. Under each node associated with an application 306, the semantic graph provides nodes for all solution methods 316 that can impact that specific requirement 304. In some cases, each solution method 316 may be defined using a text file or other user-editable file, which may allow users to modify the solution methods 316 without having to modify the actual automation tool.

By separating the solution methods 316 among the branches 314 based on the percentage thresholds or other indicators of differences between desired and actual design characteristics, it is possible to narrow down the list of potential solution methods 316 to be used in any given design situation through intelligent selection. In this example, the intelligent selection is based on the differences between the requirements 304 and the actual metrics for a logic device design. If a design fails to satisfy a specific requirement 304, the solution methods 316 associated with that specific requirement 304 can be used to modify the design and (hopefully) satisfy the specific requirement 304. This is useful since some solution methods 316 may provide smaller percentages of improvement or other smaller amounts of improvement for a particular requirement 304, while other solution methods 316 may provide larger percentages of improvement or other larger amounts of improvement for the particular requirement 304. The approach shown here can therefore help to select solution methods 316 having a better chance of resolving differences between the requirements 302, 304 and last best-fit metrics.

In this particular example, each solution method 316 may include (or is identified in the graph with) a formula that can be used to identify an expected improvement in the metric for the associated requirement 304. For many solution methods 316, a logical data value can be used, which may provide significant impact to resolving requirements efficiently. In other cases, a solution method 316 may be blindly applied whenever a requirement 304 is not met. When a logical data value is present, the logical data value can define how that solution method 316 is to be applied, and the data values may be found based on mismatches between a requirement 304 and previously-defined or newly-directed test cases to populate effects. A solution method 316 may be selected for use if its estimated impact would cause a logic device design to be updated in a manner that likely satisfies the associated requirement 304. The selected solution method 316 can be used to identify one or more updated constraints to be used in creating a new design for the logic device 102a-102d.

As an example of this, if a proposed logic device design fails to satisfy the timing closure requirement 304 for an application 306, the automation tool may take an HLS report of estimated (prior to place and route) clock frequency and compare that to the user's required clock frequency. The default clock skew may be set to 20% for the HLS tool. If the prior design attempt missed the timing requirement by 7%, a data value of 13% (20%−7%) may be used for defining a solution method clock skew. This may or may not work depending on whether the tool used for place and route (such as VIVADO) can keep the clock skew to within the identified 13%. Therefore, the automated design tool 220 may initially iterate on faster HLS builds and then run the place and route tool when either (i) HLS reported requirements are met or (ii) SAP values are required to be updated. For instance, if HLS-indicated timing closure can be met after applying a 13% allowed clock skew (but it is learned that the timing fails later after running place and route), the place and route tool can be run with timing optimizations enabled and (if still failing) can change the clock skew solution method 316 to indicate the minimum SAP value that can be used. For this calculation, the timing report can be used to show the percentage of clock frequency missed, and that value can be subtracted from the value last used. The ability to establish limits for each solution method 316 allows constraining of the solution method 316 to prevent logic device builds that will not satisfy the latency, resource, power, and timing closure requirements 304. This setting of limits also prevents many iterations from occurring that are likely to result in poor or unusable logic device build choices.

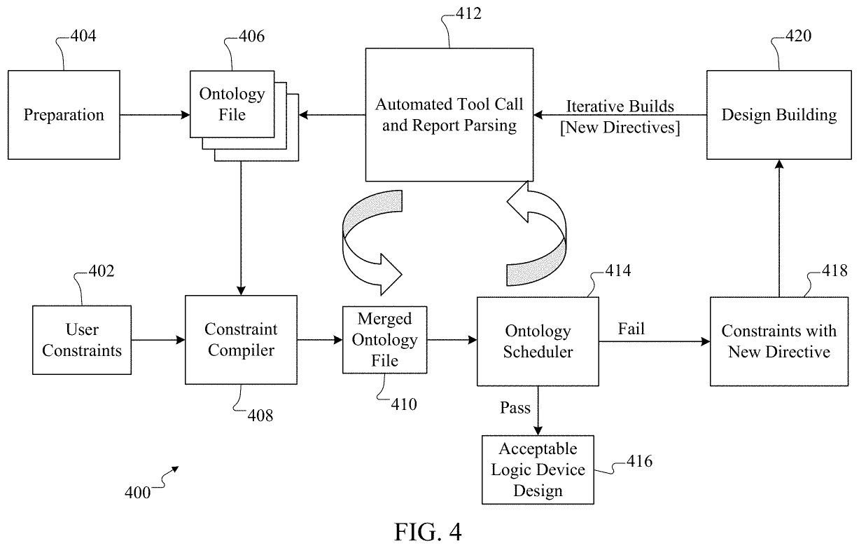

FIG. 4 illustrates an example iterative process 400 for identifying design parameters for logic devices during automated design according to this disclosure. In particular, FIG. 4 illustrates how the identification 300 shown in FIG. 3 can be used as part of a larger technique in which the design parameters are iteratively modified based on (among other things) the solution methods 316 selected for each application's requirements 304.

As shown in FIG. 4, user constraints 402 are obtained, such as when the user constraints 402 include constraints from the at least one user constraint file 204. A preparation function 404 is used to generate ontology files 406, where the ontology files 406 may contain constraints and requirements defined by an ontology (such as from the ontology-based information 216). In some cases, the user constraints 402 may define at least some of the application-level requirements 304, and the ontology files 406 may define at least some of the chip-level requirements 302. A constraint compiler function 408 can combine the various constraints and other information to produce a merged ontology file 410. The merged ontology file 410 may contain all of the constraints to be applied to the design of a logic device 102a-102d and other information to be used during the design of the logic device 102a-102d. Each of the ontology files 406 and the merged ontology file 410 may have any suitable form, such as a YAML file (note that “YAML” is a recursive acronym for “YAML Ain't Markup Language,” meaning it is an acronym that refers to itself).

An automated tool call and report parsing function 412 and an ontology scheduler function 414 can be used as part of an iterative process to generate a design for the logic device 102a-102d. The automated tool call and report parsing function 412 may be used to invoke various functions (such as the additional tools 230, 232) in order to generate an actual design “build” for a logic device 102a-102d. The automated tool call and report parsing function 412 may also be used to parse information about the actual design build for the logic device 102a-102d, such as to identify the actual latency, resource, power, and timing closure requirements of the design. The ontology scheduler function 414 may analyze the actual characteristics of the design and determine whether one or more of the actual characteristics exceeds any of the requirements 302, 304 applicable to the design. If not, the ontology scheduler function 414 may use the current design as an acceptable logic device design 416. Note that a single acceptable logic device design 416 might be identified, or multiple acceptable logic device designs 416 might be identified and compared to select an optimal or desired design.

If one or more of the actual characteristics exceeds any of the requirements 302, 304, the ontology scheduler function 414 can select one or more solution methods 316 to be applied to the current design in order to generate updated constraints 418, which may further limit how the logic device 102a-102d can be designed. The updated constraints 418 are provided to a design building function 420, which may represent at least part of the automated design tool 220. The design building function 420 can generate new design parameters for a logic device design, and the new design parameters can be provided to the automated tool call and report parsing function 412 to use as described above. Ideally, after one or more iterations, the new design parameters will eventually satisfy all of the constraints 402 as specified by the user (such as all requirements 302, 304).

As shown here, the results of each attempted build (as analyzed by the automated tool call and report parsing function 412) can be fed back to the ontology scheduler function 414 via the ontology files 406 and the merged ontology file 410. This feedback can be used to help provide for higher accuracy during the design process. Also, in some cases, the updated constraints 418 may be associated with at least one new directive, where each new directive can be associated with an estimated impact or effect of the change to the updated constraints 418. The estimated impact or effect can be calibrated by the design building function 420, which means that the design building function 420 may make design changes to a logic device design to maximize the impact or effect of that directive. In particular embodiments, only one changed directive may be applied for each iteration of the design process, so there is no question of the contribution from multiple competing directives. Also, the actual impact or effect can be updated once the design building function 420 actually generates a new design that is analyzed.

Since the change to the updated constraints 418 is based on the selected solution method 316 applied by the ontology scheduler function 414, this allows (after multiple iterations) the ontology scheduler function 414 to learn how certain changes in the updated constraints 418 may result in changes to the logic device design as determined by the design building function 420. Essentially, the ontology scheduler function 414 can be trained to pre-calculate a combination of directives that has a good chance of satisfying all requirements 302, 304 in an optimal manner. In some cases, the ontology scheduler function 414 may store this type of knowledge in Resource Description Framework (RDF) graphs, which can be used to predict the results of the different solution methods 316. Of course, other approaches for storing this knowledge may be used. The ability to “pre-estimate” the performance of the next iteration of the design process can help to reduce or minimize the number of iterations and therefore the run-time of the automation tool.

Note that each failed or unsatisfied requirement 302 or 304 may be associated with a number of solution methods 316, and each solution method 316 may or may not have an impact on other requirements. In the timing closure example described above, for instance, there may be multiple solution methods 316 that might be used to provide a solution satisfying the timing closure requirement. Thus, multiple iterations through the process 400 may occur while changing parameters using these individual solution methods 316. This may allow the impacts of the solution methods 316 on the various requirements 302, 304 to be learned and used more effectively.

In some embodiments, one intent here can be to select a combination of constraints that satisfies a particular failed requirement 302, 304 by a smallest achievable amount. Also, in some embodiments, some directives may always be applied when failing a particular requirement 302 or 304, such as when those directives have very little negative impact to other requirements. For cases where there are multiple loops or iterations to identify impacts or effects of directive changes and there is a need or desire to improve latency, the automation tool may start at the largest latency loop and unroll or flatten it, although multiple loops may need these directives depending on how much optimization is needed for latency or resources. In addition, in some embodiments, certain requirements 302, 304 may be satisfied in a particular order during the iterative process. For instance, a design for a logic device 102a-102d may first be required to satisfy any latency requirements 302 and 304, then any resource requirements 302 and 304, then any timing closure requirements 302 and 304, and then any power requirements 302 and 304. Once the latency requirements 302 and 304 are satisfied, iterations may occur to satisfy the resource requirements 302 and 304 while still satisfying the latency requirements 302 and 304. Once the resource requirements 302 and 304 are satisfied, iterations may occur to satisfy the timing closure requirements 302 and 304 while still satisfying the latency and resource requirements 302 and 304. A similar process may occur to satisfy the power requirements 302 and 304.

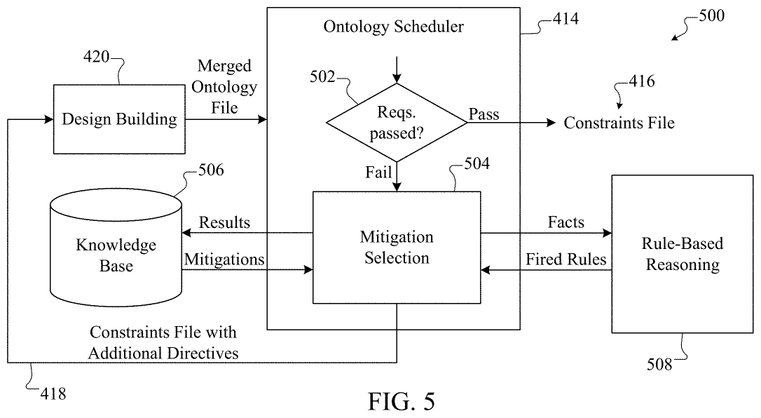

FIG. 5 illustrates an example process 500 for modifying design parameters for logic devices during automated design according to this disclosure. In particular, FIG. 5 illustrates how the ontology scheduler function 414 shown in FIG. 4 may select solution methods 316 for use in the process 400 where the design parameters are iteratively modified.

As shown in FIG. 5, a determination 502 is made by the ontology scheduler function 414 whether a current design for a logic device 102a-102d satisfies the applicable requirements 302, 304. If it does, the current constraints and other information can be output as part of an acceptable logic device design 416. If it does not, the ontology scheduler function 414 performs a mitigation selection function 504, which determines which mitigations (solution methods 316) should be applied to the current design in order to produce the updated constraints 418.

In this example, the mitigation selection function 504 can select one or more solution methods 316 based on knowledge in a knowledge base 506 and/or one or more rules used by a rule-based reasoning system 508. The knowledge base 506 may store RDF graphs or other graphs embodying information about how constraints or other design parameters may be modified to achieve desired changes in the design of a logic device. Of course, the information may be stored in any other suitable manner. The rule-based reasoning system 508 may use rules rather than knowledge graphs to embody information about how constraints or other design parameters may be modified to achieve desired changes in the design of a logic device. The rule-based reasoning system 508 includes any suitable system that uses rules to identify mitigations for logic device designs, such as a system that uses JAVA-based reasoning software or a system that uses the C Language Integrated Production System (CLIPS) rule-based programming language.

Note that while both the knowledge base 506 and the rule-based reasoning system 508 are shown here, only one of these may be used in other embodiments. However implemented, this allows the ontology scheduler function 414 to select mitigations based on estimated improvements in the relevant metrics associated with the requirements 302, 304. As noted above, one goal here may be trying to meet the specified requirements 302, 304 for the logic device 102a-102d with little or no overshoot of the requirements 302, 304.

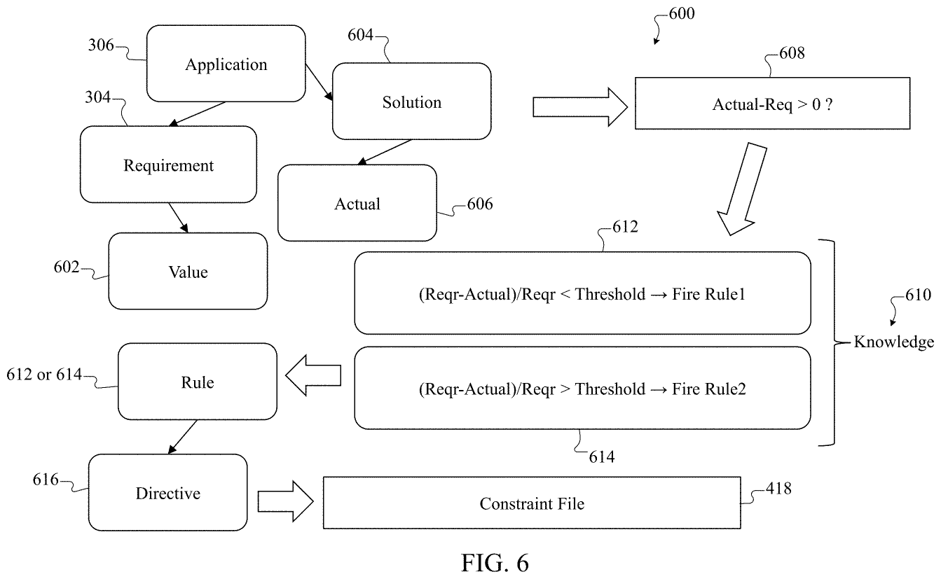

FIG. 6 illustrates an example summarized process 600 for usage of an ontology during automated design of logic devices according to this disclosure. In particular, the process 600 shown here summarizes how the various components shown in FIGS. 3 through 5 can be used during automated design of logic devices.

As shown in FIG. 6, an application 306 is associated with a specific requirement 304, such as a latency, resource, power, or timing closure requirement. The requirement 304 has a specific requirement value 602 to be satisfied. For example, the requirement value 602 may represent the maximum value of the latency, resource, power, or timing closure requirement 304 that is deemed to be acceptable.

In the example of FIG. 6, the mitigation involves the use of knowledge 610, which may be embodied in the knowledge base 506 or the rule-based reasoning system 508. Overall, the purpose of the knowledge 610 is to select one or more mitigations to improve the solution 604. For example, the one or more mitigations may be selected based on how far the actual value 606 diverges from the requirement value 602. Possible mitigations represent different solution methods 316, and the effects of the solution methods 316 may be known or estimated (such as based on prior iterations). This allows, for example, one or more solution methods 316 to be selected while taking into account side effects, such as when one solution method 316 achieves a desired effect relative to the requirement value 602 but also impacts a different requirement 304. In this example, the knowledge 610 takes the form of different rules 612, 614 to be applied depending on the amount of divergence between the values 602 and 606. One of the rules 612 or 614 is used to create a directive 616 that involves modifying a particular constraint, which leads to the generation of a file containing the updated constraints 418. The updated constraints 418 may then be used to produce another solution 604, which can be processed in the same manner.

The automated design tool 220 may generate a design solution 604, which represents a potential design of a logic device 102a-102d that will execute the application 306. The design solution 604 has an actual value 606 of a characteristic, such as an actual latency, resource, power, or timing closure value. The requirement value 602 is compared to the actual value 606 in order to determine whether the design solution 604 satisfies this specific requirement 304. If not, some form of mitigation is needed in order to modify the design solution 604 so that the specific requirement 304 can be satisfied.

As noted in the discussion above, the solution methods 316 may have overlapping effects on different requirements 302, 304. For example, increasing fabric vectorization for an application by a factor of two may cause an increase in fabric resource usage by a factor of about two and an increase in power usage by a factor of about two for those vectorized resources. Thus, a solution method 316 that varies the fabric vectorization may impact both resource and power requirements 304 for that application, as well as resource and power requirements 302 for the overall logic device. The effects of applying each solution method 316 can be pre-trained or otherwise estimated to a large extent by the ontology scheduler function 414 in order to provide efficient guidance for solving the requirements 302 and 304 simultaneously. These logical effects are also SAP values, which can be adjusted automatically after receiving results from a design attempt. One example result of this may be that, when providing design solutions, the automated design tool 220 may apply only as many resources as needed to solve latency. In some cases, this can be done logically through a difference between “latest selected best” solution metrics and where the solution needs to be modified in order to satisfy one or more requirements. For instance, if an application has three loops, the resources and latency of each loop can be considered and utilized separately.

Assume a latency requirement is 4 milliseconds. If a first loop has a latency of 1 millisecond, a second loop has a latency of 2 milliseconds, and a third loop has a latency of 3 milliseconds, the latency requirement would fail by 2 milliseconds (assuming the loops are executed sequentially). Logical effects may be used to select which of the loops should increase vectorization. In conjunction with this, the resources utilized for each loop may be stored in a knowledge graph, and logical effects may be used to determine that increasing vectorization by a factor of two uses twice as many resources under the loop vectorized. Since the first loop only has a latency of 1 millisecond and the second loop only has a latency of 2 milliseconds, neither loop may (by itself) be vectorized to achieve the necessary 2 millisecond reduction needed in total latency. Thus, the third loop can be selected with a vectorization of data value of four, which would result in the third loop achieving a latency of 0.75 milliseconds (defined as 3 milliseconds divided by the vectorization data value of four). The total latency would then equal 3.75 milliseconds for all three loops. In this case, a solution method 316 may be applied to unroll the third loop.

However, assume that estimating the logical effect of increasing resources for the third loop by a factor of four would exceed available resources. In that case, additional solution methods 316 may be explored. The additional solution methods 316 may indicate that there are many different combinations of design modifications that might attain a solution for all requirements 302, 304. In the same example, for instance, increasing vectorization for the third loop may exceed available resources for all applications 306, so the algorithm may include links to additional solution methods 316 to compensate or select application kernels that can be executed using different resources. For example, to free up additional fabric resources, it may be possible to execute part or all of the third loop using either one or more engines or cores 104 or one or more embedded processing devices 132, and the algorithm may consider utilizing load sharing between the one or more engines or cores 104 and the one or more embedded processing devices 132.

There may be other graphs, rules, or other knowledge relating to logical effects that may be used to perform a mitigation in order to identify a possible design solution. For example, instead of two applications 306 defined (in a constraint file) to be run simultaneously, it may be possible to execute the applications 306 sequentially (one at a time). However, this solution method 316 may only be viable if the applications 306 can be executed within the smallest latency required for one application. As a particular example, if running two simultaneous applications 306 requires a latency of 10 milliseconds and 5 milliseconds, respectfully, a solution method 316 might indicate that it is possible to use certain application kernels that can each complete execution in 2.5 milliseconds (including run-time reload time). Thus, the solution method 316 may be used to indicate that the two applications 306 may successfully be executed serially within the smaller 5 millisecond latency time. Note that this example assumes the automation tool can account for data streaming and buffering requirements so that, if data arrives for the two applications 306 simultaneously, additional buffer resources or engine/core memories can be used to store the data (since the applications 306 are executed sequentially and not simultaneously as originally expected). The automation tool here may also take into account run-time re-load values, meaning the time needed to load resources with instructions or data for the second application. For instance, if utilizing the same fabric resources for multiple applications 306 and using partial reconfiguration, the partial reconfiguration time is added to the calculated estimate latency time to make sure that the overall latency is still satisfied. The same is true for embedded processor instruction re-load and engine/core instruction (program memory) reload time.

In some cases, various information (such as run-time reload times) may be known ahead of time without the need for trial runs or iterations through the design process. For example, partial reconfiguration times for a specific platform and a specific silicon technology may be determined using a formula based on die rectangle area to be reconfigured by data rate of incoming configuration data rate, plus fixed overhead. This can be used to calculate how much time would be required to utilize common resources for multiple kernels or applications. These formulas can be part of the knowledge graphs or other knowledge available to the automated design tool 220. For the engines or cores 104, program memory re-load might be performed while a prior application is still running, such as through the use of dual program memory banks (where one can be read while other is being loaded). This may allow a fixed time period, such as about thirty nanoseconds, to switch from one application to another application using the same engine(s) or cores(s) 104. In this way, the combined latency can take into account all of the various latencies, including run-time switching effects. In addition, the automation tool may take into account the data movements required for switching between applications. The maximum time between the instruction reload and the data movement for the engines or cores 104 can be used, since both actions can be performed simultaneously when switching applications.

It should be noted that the above example has described performing multiple iterations of the design process to identify knowledge that can be used by the ontology scheduler function 414 to more intelligently select solution methods 316 to be applied to a particular logic device design. This is useful when certain design parameters can be modified and the resulting design changes can be determined within reasonably-short time periods. For example, some design changes may be calculated in minutes or tens of minutes, but other design changes may require hours or even days to calculate. Thus, it may be necessary or desirable to avoid large numbers of iterations and to avoid combinations of solution methods 316 that do not have predicted performances likely to achieve adequate results to satisfy relevant requirements 302, 304. The automated design tool 220 can achieve this by focusing on the use of quality solution methods 316, such as by using predicted results of each solution method 316 and accumulating all portions of each application 306 to ensure all requirements 302, 304 are met. For example, each solution method 316 may have a default value for its predictive benefit, such as a default percentage impact. For different applications 306 and chip designs, those default impacts may be or may become stale and therefore require more accurate updates. Since using multiple solution methods 316 at the same time can make it difficult to identify which results come from each solution method 316, calibration of the solution method impacts can be performed at selected times, such as when use of the default values results in vastly different results than predicted. During the calibration, one solution method 316 may be selected at a time and modified, although it is also possible to parallelize the calibration using different solution methods 316 for different applications to minimize the total combinations of builds needed to update the impacts.

It should also be noted here that the various techniques and processes shown in FIGS. 3 through 6 have often been described as being used to design the engines or cores 104 of the logic device 102a-102d. However, the same or similar techniques and processes may be used to design other aspects of the logic device 102a-102d, such as to design data movement components 108 and a run-time scheduler 134 that satisfy various constraints.

In the discussion above, it has also been assumed that the automated design tool 220 is being used during compile-time, meaning the automated design tool 220 is being used when a build for logic devices 102a-102d is being created and compiled. Once a suitable design is identified and the resulting build is created, the logic devices 102a-102d can be configured and programmed based on the resulting build. When placed into actual operation, the logic devices 102a-102d can perform various run-time actions based on information provided during compile-time to support the efficient execution of the applications 306 by the engines or cores 104 or other components of the logic devices 102a-102d.

As one example of this, performance metrics that are generated after various solution methods 316 are applied to a logic device design can be stored in or otherwise made available to the run-time scheduler 134. The run-time scheduler 134 can control switching of applications and data movements in the logic device 102a-102d during run-time. The data movements can include operations such as buffing, data pre-fetching, instruction memory re-loading, generation of flags for timing control, and data movements for applications. In some cases, controlling the various data movements may be done with the goal of minimizing application power, such as through the use of locality of data and minimization of bottlenecks. Another goal may be to satisfy required application switching times. Different approaches can have different application switching times, different data pre-load times needed to start applications on time, and different instruction pre-load times. The performance metrics can be inserted into or otherwise made available to the run-time scheduler 134, such as based on metrics of the selected best fit applications. The run-time scheduler 134 may use this information during run-time when determining when and how to perform various instruction and data movements to satisfy latencies or other requirements.

As another example of this, one goal of compile-time and run-time control may be to select available resources that provide needed latencies and powers. The automated design tool 220 may allow a user to enter application switching times, such as partial reconfiguration times and data movement latencies from an external interface to an application 306 running on an engine or core 104 (plus any overhead or top-level power and latency requirements that need to be included to satisfy chip-level requirements 302). Assuming a logic device 102a-102d cannot build a new application 306 fast enough at run-time, multiple builds for each application 306 can be compiled and made available at run-time (but not necessarily available at the same time). For instance, the same behavioral source code application may be compiled into different kernels, such as one version that executes faster (but at a higher power requirement) and another version that executes slower (but at a lower power requirement). It is also possible to build applications or kernels making up one or more applications using different resources, powers, or latencies. This would allow the run-time scheduler 134 to select an application build that makes the most sense at that particular run-time.

As noted above, various applications 306 may be defined as being “load on demand” or “run on demand.” Load on demand application switching is one feature that can be supported by the automated design tool 220, meaning the automated design tool 220 can create a logic device build that allows one application 306 to be loaded while or after another application 306 is executing. During this type of application switching, partial reconfiguration (if enabled) can be automatically performed in order to prepare resources used by the first application 306 for use by the subsequent second application 306. Once partial reconfiguration is completed, the resources are available to perform the second application 306, and partial reconfiguration can continue any number of times. The automated design tool 220 can insert code to automatically perform partial reconfiguration when needed. For instance, an application 306 or part of an application 306 can be selected by a user to support partial reconfiguration and share the same resources as another application 306, and the automated design tool 220 can automatically insert the partial reconfiguration code for that application 306 or that part of an application 306. Note that this load on demand feature may also be used for embedded processing devices 132, although this feature would take the form of a load of instructions from memory (such as from an external memory like a Flash or DDR memory). The automated design tool 220 can create, and the run-time scheduler 134 can execute, the logic for loading instructions to start execution of one application 306 after execution of another application 306 on an embedded processing device 132 is completed.

To support application switching or other functionality, the run-time scheduler 134 can also be configured to adjust fabric resources (such as in the interface 106). Logic devices 102a-102d may often be designed with fabric resources already available for use with all applications 306 on all engines or cores 104. The switching between fabric resources often utilizes electrical switches forming multiplexers and de-multiplexers, where switching between applications 306 involves setting switch signals to appropriate values so that the electrical switches allow data to stream in and out as needed. This switching is rapid and typically requires one or two fabric clock cycles.

To support instruction re-loading (such as during an application switch), the actual program memory in an engine or core 104 can be preloaded (such as by using dual program memory banks as described above). As a particular example, each engine or core 104 may include two 8 kB memories, where instructions can be written into one while instructions are being read from the other. This type of approach may help to reduce or avoid the use of dedicated resources for each application 306, such as dedicated fabric resources. Since re-load can be performed for a second application 306 in parallel with the execution of a first application 306, application switching within each engine or core 104 may require a very small amount of time (such as about 100 nanoseconds or less) to switch the program memory being used, assuming needed data is available for the second application 306. If needed data for the second application 306 is not available, the data memory for the engine or core 104 may be loaded. Assuming the engine or core 104 also has dual data memories, the run-time scheduler 134 can be informed by the results of the solution methods 316 when to start loading the next application's data.

The automated design tool 220 can further be configured at compile-time to build the logic used for pre-fetching data or instructions from external resources, buffering or caching the data or instructions, and sending the data or instructions to destination resources. A central scheduler of the logic device 102a-102d may be used to inform data movers and the run-time scheduler 134 about when an application 306 needs to start execution. The pre-loading of data and instructions can then automatically be performed based on performance metrics associated with the previously-applied solution methods 316, which allows for externally-provided application start times. The run-time scheduler 134 also supports load-sharing of applications 306 across multiple logic devices 102a-102d and associated data movements, which is described in the related patent documents. The data movers include features allowing for scheduling of applications 306 to be executed by external logic devices, such as based on failures and over-temperature conditions, which is also described in the related patent documents.

In addition, as noted above, it is possible for the automated design tool 220 to pre-build multiple versions of the same application 306. For example, there may be one application kernel that minimizes latency and another application kernel that minimizes power for the sample application 306. This allows the most appropriate version of the application 306 to be selected at run-time. As another example, during different modes of radar operation, there may be different performance requirements, such as one set of requirements for search mode and another set of requirements for track mode. An application 306 may perform digital down-selection and filtering of analog-to-digital converter (ADC) outputs utilizing many narrow beams during track mode, and the application 306 may use a wider bandwidth and fewer beams during search mode. Instead of designing common logic that can be used during both modes, the same application 306 can be compiled differently to create different versions that both minimize power, but one version for track mode may have access to more resources in order to support the use of more beams. This ability to re-load applications 306 into the same engines or cores 104 at run-time allows for greater efficiency and reduced power.

As can be seen here, the automated design tool 220 can support the use of various techniques that reduce the need for logic device engineers to be subject matter experts of target technologies and tools. This can be accomplished by iteratively performing design operations to create logic device designs using AI/ML learning and an ontology function that can embed expert knowledge and numerous solution methods 316 and that can select the best fit solution. A user here may only need to specify higher-level requirements, such as latency, resources, power, timing closure, or other requirements. Specific lower-level requirements need not be specified by the user (although nothing prevents consideration of such inputs). This can significantly reduce or completely remove the presence of human decisions in the iterating looping until all requirements 302, 304 are satisfied, supporting the automatic design of logic devices 102a-102d. Moreover, the AI/ML learning and ontology components of the automated design tool 220 can be used to reduce solution space explorations, which helps with finding design solutions faster. As new design solutions are explored, performance metrics that result can be compared with a user's requirements to provide intelligent subsequent iterations of the design loop (with likely improved results) until all requirements 302, 304 are optimally reached or at least satisfied, and the performance metrics can be used to support other functions (such as run-time scheduling).

Although FIGS. 3 through 6 illustrate example techniques and processes for identifying design parameters for logic devices 102a-102d during automated design and related details, various changes may be made to FIGS. 3 through 6. For example, various components in FIGS. 3 through 6 may be combined, further subdivided, replicated, omitted, or rearranged and additional components may be added according to particular needs. Also, the specific tools, ontologies, and processes described above may vary based on, among other things, the specific logic device 102a-102d being designed. In addition, one or more logic devices 102a-102d may be designed using any other suitable automation tool having various capabilities as described in this patent document.

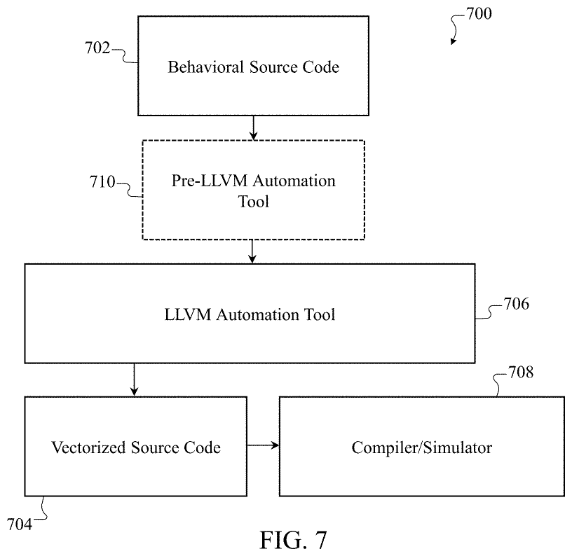

FIG. 7 illustrates an example technique 700 for vectorizing behavioral source code for use during automated design of logic devices according to this disclosure. For ease of explanation, the technique 700 is described as being used to design one or more logic devices 102a-102d in the system 100 of FIG. 1 above. However, the technique 700 may be used to design any other suitable logic device(s), and the logic device(s) may be used in any suitable system(s).

As shown in FIG. 7, behavioral source code 702 can be obtained and processed to produce vectorized source code 704. The vectorized source code 704 essentially represents the logic of the behavioral source code 702, but the vectorized source code 704 maps the logic of the behavioral source code 702 to an array of engines or cores 104 in a logic device 102a-102d. This is performed by an LLVM automation tool 706, which may form a part of the automated design tool 220.

Among other things, the LLVM automation tool 706 can converts C, C++, or other behavioral source code 702 into a suitable language for the engines or cores 104 of the logic device 102a-102d. The LLVM automation tool 706 can also auto-vectorize the behavioral source code 702 by converting certain operations into vector operations. For instance, some engines or cores 104 may be able to perform eight floating-point operations and one pipelined scalar operation per nanosecond, and the

LLVM automation tool 706 can vectorize the behavioral source code 702 so that operations performed serially in the behavioral source code 702 are performed simultaneously using vectors in the vectorized source code 704. The LLVM automation tool 706 can similarly take advantage of other hardware features of the logic device 102a-102d to achieve the lowest latency results. In some cases, a user can specify a desired precision for certain operations, which allows the user to trade accuracy against latency as needed or desired.

In some embodiments, an optimized library of functions and optimization strategies can be supported by the LLVM automation tool 706 when generating the vectorized source code 704. The functions and optimization strategies can be identified by converting various algorithms and mathematical operations into vectorized source code 704 in different ways and comparing the execution results of the vectorized source code 704. This allows the library to be tuned to the specific hardware of the logic device 102a-102d.

In this example, the vectorized source code 704 can be provided to a compiler or simulator 708 for use. Depending on the circumstances, the compiler or simulator 708 may compile the vectorized source code 704 into executable code that can be provided to the engines or cores 104 of one or more logic devices 102a-102d for actual execution. The compiler or simulator 708 may also simulate the execution of the vectorized source code 704, such as to determine the latency and timing closure of the vectorized source code 704. Note that the vectorized source code 704 may be used in any other suitable manner here. The simulated latency (such as of applications running on logic device engines or cores 104) may be used by the automated design tool 220 as wrappers to the user-provided behavioral source code to allow fast behavioral simulations with cycle-accurate or near-cycle-accurate simulations.

In some embodiments, the LLVM automation tool 706 uses behavioral source code 702 that has been conditioned in a specific format and added pragmas. The LLVM automation tool 706 can also operate on a single kernel, which is a program to be run in an engine or core 104. A pre-LLVM automation tool 710 may optionally be used to perform behavioral source code modifications to allow direct flow into the LLVM automation tool 706 and provide any chip-level data movement and algorithm latency reducing optimizations.

Here, the pre-LLVM automation tool 710 can pre-process the behavioral source code 702 prior to processing by the LLVM automation tool 706. The pre-LLVM automation tool 710 can make desired modifications to the behavioral source code 702 in order to support easier or more effective vectorization by the LLVM automation tool 706. For example, the pre-LLVM automation tool 710 can perform parallelization of logic from the behavioral source code 702, which can help to satisfy latency requirements. The pre-LLVM automation tool 710 can also perform other application modifications for input to the LLVM automation tool 706. The pre-LLVM automation tool 710 may further identify RDMA data movement and interfaces with external chips or other external components.

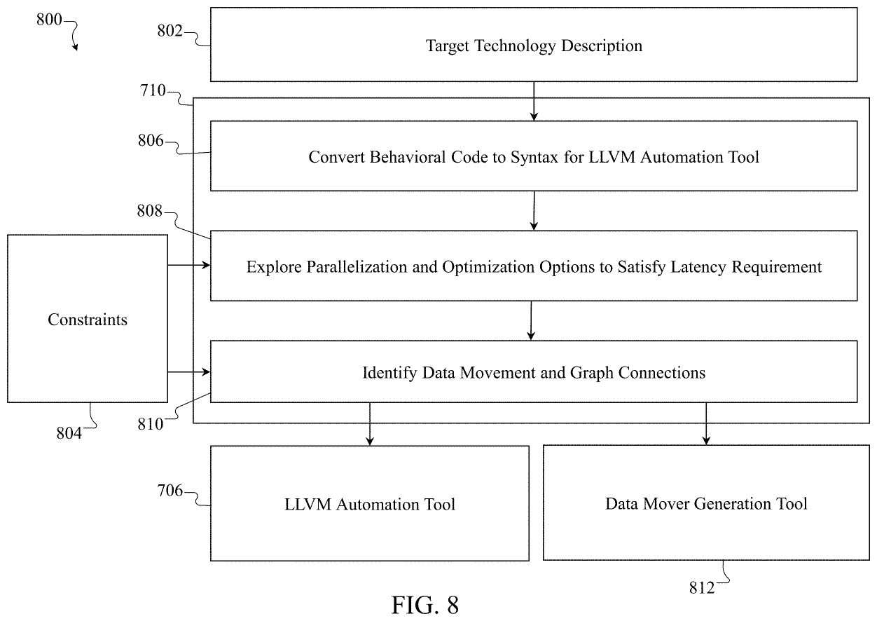

FIG. 8 illustrates an example technique 800 for modifying behavioral source code prior to vectorization for use during automated design of logic devices according to this disclosure. More specifically, FIG. 8 illustrates an example technique 800 that can be used by the pre-LLVM automation tool 710 to pre-process the behavioral source code 702 prior to input to the LLVM automation tool 706.

As shown in FIG. 8, the pre-LLVM automation tool 710 receives a target technology description 802 and constraints 804. The target technology description 802 describes the logic devices 102a-102d being designed to execute the behavioral source code 702. For example, the target technology description 802 may identify the specific types of logic devices 102a-102d being designed. The target technology description 802 may also identify the syntax or other information to be used by the logic devices 102a-102d when executing the behavioral source code 702. The constraints 804 may represent any of the constraints discussed above.

The pre-LLVM automation tool 710 here performs a syntax conversion function 806, which converts the behavioral source code 702 to a syntax used by the LLVM automation tool 706. The actual conversions performed by the conversion function 806 can vary based on a number of factors, such as the behavioral source code 702 actually being converted, the available engines or cores 104 that can be used to parallelize an application, and the syntax expected by the LLVM automation tool 706. The syntax expected by the LLVM automation tool 706 itself can vary depending on, for instance, the specific logic devices 102a-102d being designed. Example types of syntax conversions are described below.

The pre-LLVM automation tool 710 also performs a parallelization and optimization function 808, which analyzes various ways in which the behavioral source code 702 may be parallelized to execute on multiple engines or cores 104 and ways in which the behavioral source code 702 can be optimized for execution by the multiple engines or cores 104. For example, the parallelization and optimization function 808 may determine whether the behavioral source code 702 is expected to exceed a desired latency when executed by a single engine or core 104 and, if so, determine how the behavioral source code 702 might be executed by multiple engines or cores 104 to reach the desired latency. This might include identification of various ways in which data value arrays can be divided and processed in parallel by multiple engines or cores 104. Example types of parallelization approaches and optimizations are described below.

The pre-LLVM automation tool 710 further performs a data movements and graph connections identification function 810, which identifies the data movers that may be needed during execution of the parallelized and optimized behavioral source code 702. The identification function 810 can also identify connections between the data movers and other components of the logic devices 102a-102d. Example types of data movements and graph connections are described below.

The pre-LLVM automation tool 710 outputs various information to the LLVM automation tool 706, such as the pre-processed behavioral source code. The pre-LLVM automation tool 710 can also output information to a data mover generation tool 812, which may use the identified data movements and graph connections to design data movement components 108 for use by the logic devices 102a-102d during the execution of the vectorized source code 704.

The following now describes specific examples of the types of operations that may be performed by the pre-LLVM automation tool 710 during the functions 806-810. Note that these specific examples are for illustration only and that the pre-LLVM automation tool 710 may operate in other ways to perform the functions 806-810. For example, the following may be based on a specific type of logic device 102a-102d being designed, such as a particular FPGA from a particular manufacturer. Since logic devices can vary widely, the operations performed by the pre-LLVM automation tool 710 can also vary widely. Also note that the pre-LLVM automation tool 710 may support any desired subset of the functions described below.

The pre-LLVM automation tool 710 may convert multi-dimension arrays into single array indexes along with a formula for changing each variable index. For example, the array “float SignalA[outer_max][mid_max][inner_max]” may be redefined as “float SignalA[new_index],” where new_index is of size outer_max×mid_max×inner_max. The SignalA index variable may be referenced with “unsigned SigAindex=(outer index×mid_max×inner_max)+(mid index×inner_max)+(inner index).” The pre-LLVM automation tool 710 may also convert variable indexing of arrays or pointers into constant offsets or multipliers, which may prevent the use of an engine or core's scalar unit for memory accessing if the offset is a compile-time constant. For example, the code “for (int i=0, int offset=4; i<50; i++) B[i]=A[i+offset]” may be converted to “B[i]=A[i+4]” or to “const int offset=4; // and keep B[i]=A[i+offset].” The pre-LLVM automation tool 710 may add “_restrict_” to function parameter interface definitions and add “_attribute_(aligned(<size>))” to function parameter interface definitions (and replace <size> with 32 or other value for floating points or integers). The pre-LLVM automation tool 710 may replace memory calls (like malloc, calloc, and new) with array definitions.

The pre-LLVM automation tool 710 may perform parallelization, which results in reducing the behavioral source code's terminal counts and array sizes. One goal here may be to create a smaller program that can be run on multiple engines or cores 104. Ideally, once parallelized onto multiple engines or cores 104, the result of the processing would be identical to running the code on a single engine or core 104, except the latency is reduced. For example, to parallelize an application that uses “#define N_BLOCKS (16),” the pre-LLVM automation tool 710 may parallelize one block to each of sixteen engines or cores 104, thereby changing the code to “#define N_BLOCKS (1).” This can be done after the parallelization and data memory sizing tasks described below to analyze what level of parallelization should be performed. The pre-LLVM automation tool 710 may also insert pragmas into code to help the LLVM automation tool 706 provide optimized vectorization. For instance, “#pragma clang loop vectorize(enable)” may be added above the outermost loop to be vectorized.

The pre-LLVM automation tool 710 may create a top level function that passes pointers to lower-level functions, and “static inline” may be optionally added to the lower-level functions in front of function names for reduced latency. Feedback of latency results versus a user's latency requirements may allow variations in which different features are implemented, such as initially not using inline functions for reduced instruction sizes and then implementing inline functions if reduced latency is needed. The pre-LLVM automation tool 710 may also swap outer and inner loops based on data locality, which may help to optimize the loops and minimize data movements or variable address indexing into available data memory of the engines or cores 104. The data movement order can be matched by one or more RDMA controllers 128 having one or more memory buffers to re-order data. In some cases, data from a fabric buffer 126 can be written to more than one address to satisfy matching of the algorithm data memory order used by the engines or cores 104. The pre-LLVM automation tool 710 can keep track of data memory available in the engines or cores 104 as part of the search space to decide whether repeating data in the same engine or core's data memory is feasible.

The pre-LLVM automation tool 710 may make parallelization and data movement decisions based on estimated effects of latency. For example, the pre-LLVM automation tool 710 may keep a latency count of predicted speedup due to engine or core memory changes (such as copying the same data value to more than one address in the data memory of an engine or core 104) versus external memory latency (such as loading data into the engine or core data memory, possibly through a fabric buffer 126). Constant engine or core data memory offsets are efficient, but variable access in an engine or core data memory may still be faster than needing slower external data movements. The pre-LLVM automation tool 710 may keep track of internal engine or core latency by having estimates for each engine or core API function call and loop overhead, allowing trades prior to engine or core simulation. The same can be performed for latencies involving external data movements (external to the engine or core 104) to identify the impact of moving data into an engine or core 104 or between engines or cores 104. The pre-LLVM automation tool 710 can create multiple scenarios of data movements and estimate the impacts of each in order to prioritize on the most likely solutions having the lowest overall latencies with the fewest iteration attempts.

After performing predicted latency calculations, the pre-LLVM automation tool 710 may run cycle-accurate simulations of the engines or cores 104 to extract actual values and explore optimizations and down-select possible solutions. Overall latency can be based on total data movements (not just those inside the engines or cores 104). Thus, each resulting cycle-accurate engine or core latency may be combined with the associated data movement latency, which estimates latency such as from DDR memory or buffers. The data movement latency may be pre-defined at this point, or simulations may occur involving all data movements. Some cases may show that out-of-order external data access can dominate latency and cause more overall latency than the fastest engine or core simulation result. As a result, an estimate model of data access delays can be part of the upfront optimization strategies to prevent less-than-optimal attempts.

Within a constraint file, a user can specify an application's required latency. The pre-LLVM automation tool 710 can use this required value to iterate on various solutions until just passing the required latency with the highest performance per watt. For example, if satisfying latency with three engines or cores 104, using nine engines or cores 104 and getting faster-than-required latency may not be desirable. The trades of various parallelism approaches can be quickly implemented and tested. In order to identify actual latency, the simulator can be run and latency can be extracted during the next iteration.

The pre-LLVM automation tool 710 may re-order variable multi-dimensional indexes to optimize for either algorithm consecutive variable reads or writes or engine/core data memory order used for calculations. For example, “snapshot[cell][index]” may be used with an inner loop that operates on all “cell” variables before incrementing “index.” This array can be re-ordered to “snapshot[index][cell]” such that the order of data in the engine or core data memory lends itself to the same order of media access control as consecutive addresses (since non-constant jumping around in data memory may not be an efficient vectorized solution). This operation may be performed prior to changing arrays to single dimensions.

The pre-LLVM automation tool 710 may allow parallelized kernels to use a technique to indicate which variable value or range is active in each kernel, instead of using original (pre-parallelized) loop counts. Many cases of parallelizing kernels reduce loop terminal counts, which does not require additional communication or control, since each kernel operates on a portion of an original loop count. An example of a case that uses additional control is when a variable needs the group it is in to get a needed mathematical result. Here, various approaches might be used to support this functionality. These approaches may include passing values from a fabric to engines or cores 104 to indicate the variable value for each parallel kernel executed by the engines or cores 104, using multiple unique kernel sources that specify active ranges for variables, using kernel templates with different parameters passed at the graph level, and writing to an engine or core data memory location that can be read to determine the value (which is easy to update statically once before running an application fully). For example, one could use RDMA write to memory from the logic device fabric (HLS) resources once before startup and then read that data memory location at kernel start.

The pre-LLVM automation tool 710 may interface with the data mover generation tool 812 as noted above, and each engine or core 104 may require unique data. If the data is from an external interface (such as a gigabit serial interface or an external memory), the variable layout can be defined in a constraint file. Each RDMA controller 128 may contain a sequence RAM that can be populated by the pre-LLVM automation tool 710 to express the sequence of data required and possibly looped a specified number of times. For example, given a variable array called “float A[32]” that will be vectorized to sixteen kernels on sixteen engines or cores 104, each of the engines or cores 104 may have two indexes, “float A[2]” may be defined in each kernel, and loop terminal counts may be updated for that reduced size. Data from external memory may be two words per kernel, and each kernel may have a unique external data offset into the A[32] address space. It may be more efficient to access consecutive addresses (such as accessing external memory to obtain all thirty-two floating point values) and store the data in a local fabric buffer 126. An RDMA controller 128 may index into that buffer 126 with different offsets (by two in this case) for each kernel. The data memory location of each engine or core 104 can be specified by the pre-LLVM automation tool 710 since it defines the parallelization and the data memory map. Multiple data movement options may be explored by the pre-LLVM automation tool 710 here.

The pre-LLVM automation tool 710 may be used to adjust application variable data sizes. For example, the pre-LLVM automation tool 710 can sum all variables sizes in bytes (such as where complex and long data values have eight bytes each, floating point and integer data values have four bytes each, short integer data values have two bytes each, and byte data values have one byte each). The pre-LLVM automation tool 710 may store the C/C++ variable definition type of each variable for trades of parallelization and data storage fitting in data memories of the engines or cores 104. The same engine or core memory address can be used for multiple different data variables at different times, and the pre-LLVM automation tool 710 can trace data dependencies. The pre-LLVM automation tool 710 may create new global variable arrays that are used for multiple portions of an application. For cases where an original variable is used and not accessed again for remainder of application, the pre-LLVM automation tool 710 may allow that same globally-defined variable to be used for another variable storage needed later in sequence of the application. If variables are of different sizes, the pre-LLVM automation tool 710 can insert a cast to match the sizes of the added global variables. The pre-LLVM automation tool 710 may also add all variable sizes (in bytes) for a total combined engine or core data memory requirement, and that total combined value can be divided by the number of engines or cores 104 to obtain the data memory size for each individual engine or core 104. Each kernel may either fit into the available data memory per engine or core 104 (including stack and heap), or the flow of data to be supplied at run-time by a data mover can be designed to provide suitably-sized data at the proper times.

If combined variable sizes are greater than available engine or core data memory, the pre-LLVM automation tool 710 may use any of the following techniques to resolve the issue. The pre-LLVM automation tool 710 may reduce the memory required, such as by not duplicating the same data values, using smaller ping pong buffers with streaming from a fabric, or other optimizations. The pre-LLVM automation tool 710 may use streams of data (meaning multiple smaller chunks of data) from fabric interfaces (typically double bucket interfaces). The pre-LLVM automation tool 710 may use packet data and allow communications (such as through an RDMA controller 128) with other engines or cores 104. The pre-LLVM automation tool 710 may utilize cascade direct interfaces between neighboring engines or cores 104. If a vectorized portion for a single kernel uses more than the available data memory, the pre-LLVM automation tool 710 may create a trial for using more than one engine or core's data memory (such as the data memory of up to four engines or cores 104). The grouping of multiple engines or cores 104 for data-intensive applications can impact latency since there would be fewer engines or cores 104 available for parallelization. Initially, a grid of shared data memory from multiple engines or cores 104 may exclude some neighboring engines or cores 104 from being used, and prioritized localization of data in neighbor engines or cores 104 may be supported. Specific details of the design of the logic device 102a-102d may be used here. For instance, in a specific type of logic device 102a-102d, left-most columns of engines or cores 104 may lack full connectivity due to the presence of other components. Also, while some engines or cores 104 may have access to four neighboring memory blocks, other engines or cores 104 may have access to three neighboring memory blocks. Further, the fastest access to large amounts of data may be from a shared 128 kB or other memory space, and non-neighbor access can stall/block if direct memory access is allowed. A maximum of two 256-bit data memory reads per clock cycle may be possible by two engines or cores 104 if they are reading from two different data memory locations in the memory space; otherwise, a maximum of one 256-bit access may occur per clock cycle. A cascade interface may be slowed if needing data packet changes or conditionals, which may be ideal for completing media access in downstream engines or cores 104, and the alignment of cascade data available with kernel instruction location can be modeled to estimate latencies (for instance, the AIE compiler has been shown to move cascade data use and therefore may use volatile qualifiers on variable types). In addition, the pre-LLVM automation tool 710 may utilized an estimated average power per engine or core 104 (such as 0.06 watts), which can be considered when doing parallelization. If a power requirement is specified and the total planned number of engines or cores 104 multiplied by the estimated average power per engine or core 104 is near or over the power requirement in a constraint file, the pre-LLVM automation tool 710 may explore using fewer engines or cores 104 as long as priority (latency, power, and resources) is considered.

The pre-LLVM automation tool 710 may perform standard C “best coding” optimizations, such as moving mathematical operations from inner loops to outer loops in cases where a new value is not needed in each inner loop. When parallelizing an algorithm into multiple engines or cores 104, the pre-LLVM automation tool 710 may convert run-time variables or loop variables into compile-time constants when possible. For example, if a parallelization identifies a single engine or core 104 for each loop index, the loop index becomes constant for each engine or core 104. Unique parameters may be passed into an interface or defined as part of unique loaded data memory for each engine or core 104. Formula simplification may also reduce algorithm complexity and minimize associated data movements.

The pre-LLVM automation tool 710 may identify algorithms that run on common data and try to merge those algorithms into the same or neighboring engines or cores 104 (as long as this does not conflict with data dependencies). An example is a variable that is used in stages one and three of an application. The same engine or core 104 that performs stage one may also perform stage three while keeping the needed data locally in the engine or core's data memory. Another optimization is that, when a variable is set, moving code allowed by data dependencies can allow use of that variable without needing to store it from an engine or core's vector unit. The pre-LLVM automation tool 710 may use latency estimates for each behavioral structure and explore various parallelization approaches to select the lowest latency within allowed resources.

If an application cannot fit completely in an engine or core's instruction memory, the pre-LLVM automation tool 710 may utilize a technique of instruction reload while operating or may select a different application implementation that uses fewer instructions or more loops of repeatable instructions or non-inline function calls. For instruction reloading of program memory, instructions may be stored in one program memory buffer while other instructions may be concurrently read from another program memory buffer. An engine or core 104 may provide a signal to indicate when, in an instruction sequence, a bank of instructions is utilized and may be overwritten as the other bank is being read and used.

The pre-LLVM automation tool 710 may optimize to keep data in an engine or core's local data memory and registers throughout intermediate calculations to minimize memory accesses. For example, if a variable is assigned multiple times and combined with a prior value of that variable, a media access control term can be left inside MAC registers, saving the time cost of pulling a variable from data memory. Performing consecutive updates to a single variable may not always be ideal but may be prioritized in an explored solution space due to data locality. Also, behavioral source code can sometimes be re-ordered to move calculations of the same data consecutively. A count of the engine or core reload times or the engine or core data memory accesses can be performed for each trade of data sequence organization to select the likely best fit. It is also sometimes faster to re-calculate a term rather than use more data memory by storing an intermediate result to be used later. When engine or core data memory is at a premium, re-calculations of re-used terms can be explored. Certain engine or core computations (such as sine and square root functions) are slow, and engine or core data memory storage may be preferred when a variable is re-used due to the cost of re-generating that term. The latency impact estimate can also be used for each solution exploration. When re-calculations are preferred, the behavioral source code can be modified to remove a variable store and read and to instead call a mathematical function to re-create the needed local data value.

Coordinates (such as column and row coordinates) of each engine or core 104 may be automatically allocated by the pre-LLVM automation tool 710, or a user can set the coordinates used by the pre-LLVM automation tool 710. Certain engine or core locations may have reduced interface capacities due to the design of the logic device 102a-102d, which may indicate that automatic selection may favor coordinates with needed interfaces, engine or core memory accesses, or engine or core cascade groupings. The pre-LLVM automation tool 710 may keep track of used interfaces between a fabric and an engine or core 104, as well as direct memory accesses and cascade interface utilizations, to ensure a solution does not exceed available interfaces of the targeted technology.

The pre-LLVM automation tool 710 may use the application latency requirement in a constraint file to compare with the estimated latency calculated for each parallelization approach of that application. The pre-LLVM automation tool 710 may count each loop index and explore combinations that fit within the allowed number of engines or cores 104 and that are estimated to be of just under the needed latency. The approximate latency can be estimated by summing (i) the product of the number of bytes of data to be transferred and the rate that the data can be provided and (ii) the time for each vector and scalar mathematical operation (including the overhead of setting up media access control with data). The code for the engines or cores 104 does not need to be generated to obtain the estimated latency. Rather, each mathematical operation and data movement type in the behavioral source code can have an estimated latency. For example, each LLVM automation C-based API function call can be associated with a field identifying estimated latency for that operation. The pre-LLVM automation tool 710 may select the lowest latency or the smallest group of engines or cores 104 satisfying the latency requirement based on the priority of requirements in the constraints file. The pre-LLVM automation tool 710 may allow feedback of actual latency to allow re-running with either a tool-modified latency value (based on the difference detected) or an updated estimate for each type of engine or core operation. There are various factors that can influence latency, such as a pipelining feature of an engine or core's scalar unit, where the latency of a number of consecutive same operations provides a much better latency per operation than issuing unique API calls back-to-back without the ability to explore pipeline features of the engines or cores 104.

The pre-LLVM automation tool 710 may trade an amount of loop unrolling with an impact on fitting an application with a program memory size of an engine or core 104. The pre-LLVM automation tool 710 may make optimizations to reduce program memory, but this may require run-time reloading of program memory. In that case, the time for program memory reloading can be considered in trade. In addition, requiring reload of program memory may use additional fabric-to-engine/core lanes or reduced bandwidth of the lanes used for all data movements into engine/core data memories. Combined time costs for each strategy can be used to select the strategy with the overall best performance.

The pre-LLVM automation tool 710 may optimize groups of different type or size variables to capitalize on maximum vectorization. For example, eight floating point operations may be performed in an engine or core 104 per clock cycle, or 128 eight bit-by-eight bit operations may be performed in an engine or core 104 per clock cycle. The pre-LLVM automation tool 710 may group different sizes together, which involves (in some cases) changing algorithm or data order. During run-time, HLS logic can be added to check data sizes and bin different-sized variables in different engine or core data memory locations. Each section of that engine or core 104 can result in maximum vectorization for that size. In this case, the size may not be known until run-time, and each variable may be declared identically (such as a floating point or 32-bit integer).

The pre-LLVM automation tool 710 may remove conditionals from loops to the maximum extent possible, especially if they would utilize the scalar unit instead of the more-efficient vector unit of an engine or core 104. If a tool-generated solution runs out of engine or core memory due to non-ideal mapping, the pre-LLVM automation tool 710 may provide parameter array location constraints for specifying the engine/core memory in which arrays exist and the start address of each. The pre-LLVM automation tool 710 can use the number of bytes for each variable stored before to know when the next location address can start. The pre-LLVM automation tool 710 may start with the largest chunks of contiguous engine or core data memory and work towards lower chunks that are easier to fit in a remainder of the engine or core's memory. The pre-LLVM automation tool 710 may populate a graph with the location constraints or provide inputs to the automated design tool 220 that have those fields to allow creation of graphs files. The pre-LLVM automation tool 710 may also identify any heap and stack sizes required.

Note that some code types may not offer accelerated performance using multiple engines or cores 104 compared with fabric code. Behavioral source code can be parsed to count conditionals and features that may require higher latency if implemented in multiple engines or cores 104. The pre-LLVM automation tool 710 can separate out blocks of source code that are better performed in fabric (HLS) resources, and the pre-LLVM automation tool 710 can explore both fabric and engine/core execution for those blocks and allow the ontology-based solution methods to select the best fit.

In addition to investigating features that do not map efficiently to engines or cores 104, the pre-LLVM automation tool 710 can analyze data throughput needed for breaking an interface between an engine/core and the fabric. The pre-LLVM automation tool 710 can prioritize fabric logic for cases where interface bandwidths are able to keep up with the data throughput required. For example, a portion of code that is more efficient in fabric can have its inputs and outputs mapped to engine/core kernels, rather than breaking up an overall solution for multiple engines or cores 104 (since adding interfaces into and out of the engines or cores 104 may create longer latencies, especially if the engine or core interfaces are highly utilized or data throughput needs to be faster than what can be supplied).

Lowest power (typically higher latency than if only utilizing fabric and engines or cores) sometimes requires running compiled behavioral source code on external or embedded processors, such as at least one embedded processing device 132. Here, optional calls to engines or cores 104 may be used for one or more portions of an application, such as for high latency portions of an application, functionality that is called multiple times, or functionality that already exists on a chip resource. An example is an application running on a processor that calls a fast Fourier transform (FFT) operation performed by an engine or core 104 (since FFT operations can be performed with reduced latency in engines or cores 104).

The pre-LLVM automation tool 710 may support fault-tolerant automation in which the pre-LLVM automation tool 710 allows a user to identify behavioral source code or source code sections that are important to operate robustly and recover from faults. For example, pragma comments can be applied to behavioral C++ source code or other source code to identify the logic that should contain improved or maximized design robustness. Fault tolerant requirements are sometimes necessary or desirable in various applications, such as in satellites where hardware cannot be easily accessed/repaired/replaced or in electronic systems that can cause harm (such as self-driving autonomous vehicle functionality or logic that controls when a missile detonates). Here, the pre-LLVM automation tool 710 can automate the insertion of industry-standard or custom fault tolerant design features without having to express that logic in the behavioral source code itself or in target technology languages (other than to specify which behavioral source code or source code segments are associated with fault tolerant functionality).

To support the design of data movers, a sequence memory has typically been created manually for each set of data movements, where a sequence memory compiler takes a manually-generated high-level syntax and converts it into values used in sequence memory. The data mover generation tool 812 can help to remove the need for a user to define each RDMA sequence, and the tool 812 can create a sequence directly into each sequence RAM. The data order in each engine or core 104 may already be known when optimizing for latency. Buffers 126 and RDMA controllers 128 can re-order data in groups of RDMA sequence memory contents, such as a series of source address-to-destination combinations for a specified number of bytes and timing or priority control. The pre-LLVM automation tool 710 can provide the fabric logic sequence RAM with initialized values for sequence memory contents.

The run-time scheduler 134 controls the RDMA controllers 128 operating between chip resources and interfaces. This allows front end compiler-provided data movements to be performed at specified pre-load and application start times. This also allows for flow control, timing control, synchronization, and any application switching. The fields used by the run-time scheduler 134 and the data movement components 108 can come from latency reports, user constraints, and optionally run-time instructed commands for required application start times.

Although FIG. 7 illustrates one example of a technique 700 for vectorizing behavioral source code for use during automated design of logic devices 102a-102d and FIG. 8 illustrates one example of a technique 800 for modifying behavioral source code prior to vectorization for use during automated design of logic devices 102a-102d, various changes may be made to FIGS. 7 and 8. For example, the technique 700 for vectorizing behavioral source code and/or the technique 800 for modifying behavioral source code prior to vectorization may be used in any other suitable environment, which may or may not involve the automated design of logic devices 102a-102d.

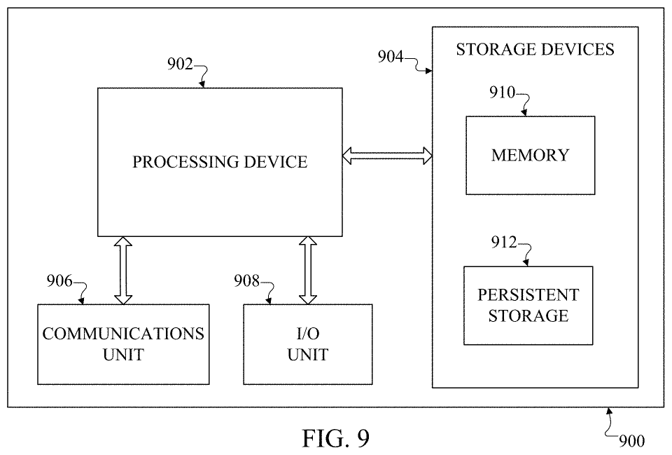

FIG. 9 illustrates an example computing device or system 900 supporting automated design of logic devices according to this disclosure. The computing device or system 900 may, for example, be used to implement the architecture 200 shown in FIG. 2 and the related processes shown in FIGS. 3 through 6 described above. The computing device or system 900 may also or alternatively be used to implement the technique 700 and/or technique 800 described above. Thus, the computing device or system 900 may be used to implement one or more functions of or related to the development or deployment of one or more designs for one or more logic devices 102a-102d.

As shown in FIG. 9, the computing device or system 900 may include at least one processing device 902, at least one optional storage device 904, at least one communications unit 906, and at least one optional input/output (I/O) unit 908. The processing device 902 may execute instructions that can be loaded into a memory 910 or other location that is local to the processing device 902. The processing device 902 includes any suitable number(s) and type(s) of processors or other processing devices in any suitable arrangement. Example types of processing devices 902 include one or more microprocessors, microcontrollers, digital signal processors (DSPs), ASICs, FPGAs, or discrete circuitry.

The memory 910 and a persistent storage 912 are examples of storage devices 904, which represent any structure(s) capable of storing and facilitating retrieval of information (such as data, program code, and/or other suitable information on a temporary or permanent basis). The memory 910 may represent a random access memory or any other suitable volatile or non-volatile storage device(s). The persistent storage 912 may contain one or more components or devices supporting longer-term storage of data, such as a read only memory, hard drive, Flash memory, or optical disc.

The communications unit 906 supports communications with other systems or devices. The communications unit 906 may support communications through any suitable physical or wireless communication link(s), such as a network or dedicated connection(s).

The I/O unit 908 allows for input and output of data. For example, the I/O unit 908 may provide a connection for user input through a keyboard, mouse, keypad, touchscreen, or other suitable input device. The I/0 unit 908 may also send output to a display or other suitable output device. Note, however, that the I/O unit 908 may be omitted if the device or system 900 does not require local I/O, such as when the device or system 900 represents a server or other component that can be accessed remotely over a network.

Although FIG. 9 illustrates one example of a computing device or system 900 supporting automated design of logic devices 102a-102d, various changes may be made to FIG. 9. For example, computing devices and systems come in a wide variety of configurations, and FIG. 9 does not limit the automated design of one or more data movers to any particular computing device or system.

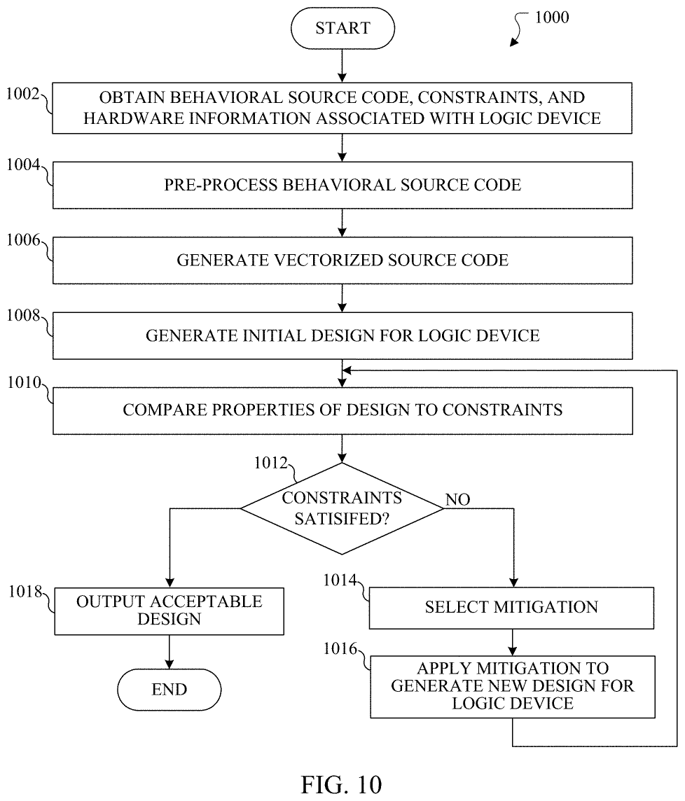

FIG. 10 illustrates an example method 1000 for automated design of logic devices according to this disclosure. For ease of explanation, the method 1000 is described as involving the design of one or more logic devices 102a-102d, which may be used within the system 100 of FIG. 1. However, the method 1000 may involve the design of any other suitable logic devices in any other suitable system.

As shown in FIG. 10, behavioral source code, constraints, and hardware information associated with a logic device being designed are obtained at step 1002. This may include, for example, receiving the user constraint file 204, hardware platform file 206, and behavioral source models, libraries, and applications 208 (which may or may not be produced by a model composer 210) as inputs to the tool suite 218. The behavioral source code is pre-processed at step 1004, and vectorized source code is generated at step 1006. This may include, for example, the automated design tool 220 using the pre-LLVM automation tool 710 to adjust the syntax of the behavioral source code, parallelize the behavioral source code, and identify data movements for the behavioral source code. This may also include the automated design tool 220 using the LLVM automation tool 706 to convert the pre-processed behavioral source code into vectorized code.

An initial design for one or more logic devices is generated at step 1008. This may include, for example, the automated design tool 220 using the ontology-based information 216 to generate an initial design for the logic devices 102a-102d based on the behavioral source code, constraints, and hardware information. The initial design may be based on prior logic device designs for similar source code, an initial assignment of applications to engines or cores 104 or other hardware resources of a logic device, or other suitable logic. Properties of the initial logic device design are determined and compared to the constraints at step 1010. This may include, for example, the automated design tool 220 estimating the latency, resource, and power of the logic device design at the chip-level and estimating the latency, resource, power, and timing closure for each application of the logic device design. This may also include the automated design tool 220 comparing the determined properties to the constraints in order to determine whether all constraints have been satisfied at step 1012.

If not all constraints have been satisfied, a mitigation is selected at step 1014 and applied to generate a new design for the logic device at step 1016. This may include, for example, the automated design tool 220 applying one or more solution methods 316 to the current design in order to modify the current design and generate the new design. The one or more solution methods 316 may be selected as being the technique or techniques that are likely (under the current circumstances) to result in an improvement in the logic device design relative to one or more constraints that are not satisfied. As a particular example, this may include the automated design tool 220 accessing the knowledge base 506 and/or the rule-based reasoning system 508 to identify one or more mitigations that might be applied. This may also include the automated design tool 220 applying the one or more solution methods 316 to the current design in order to modify the current design and generate the new design. The process then returns to step 1010 to determine whether the new logic device design satisfies all of the constraints.

Ideally, at some point, a logic device design satisfies all constraints at step 1010, and the logic device design is output as a potentially-acceptable design at step 1018. This may include, for example, the tool suite 218 converting the current design of the logic devices 102a-102d into a logic device build. Note that if multiple designs are identified as satisfying all constraints, additional processing may occur, such as to determine which design minimizes power consumption or resource usage among the acceptable designs. Also note that if no design is identified as satisfying all constraints, priorities may be applied to select one or more designs that satisfy one or more higher-priority constraints (even if one or more lower-priority constraints are not satisfied).

Although FIG. 10 illustrates one example of a method 1000 for automated design of logic devices 102a-102d, various changes may be made to FIG. 10. For example, while shown as a series of steps, various steps in FIG. 10 may overlap, occur in parallel, occur in a different order, or occur any number of times.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software or hardware components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
obtaining behavioral source code defining logic to be performed using at least one logic device, hardware information associated with the at least one logic device, and constraints identifying user requirements associated with the at least one logic device; and
generating a design for the at least one logic device using the behavioral source code, the hardware information, and the constraints, the design enabling the at least one logic device to execute the logic while satisfying the user requirements, the design generated using a machine learning/artificial intelligence (ML/AI) algorithm that iteratively modifies potential designs to meet the user requirements.

2. The method of claim 1, wherein the ML/AI algorithm iteratively:
determines whether a current design for the at least one logic device satisfies the user requirements; and
if not, selects at least one mitigation and applies the at least one mitigation to the current design for the at least one logic device in order to generate a new design for the at least one logic device.

3. The method of claim 2, wherein:
the at least one mitigation comprises at least one solution method; and
the at least one solution method is selected based on knowledge of how the at least one solution method affects the design for the at least one logic device relative to at least one of the user requirements.

4. The method of claim 3, wherein the at least one solution method is selected from among multiple solution methods based on a difference between (i) an actual value of a characteristic of the current design for the at least one logic device and (ii) a required value of the characteristic as specified by at least one of the user requirements.

5. The method of claim 1, wherein the user requirements comprise latency, resource, power, and clock frequency requirements.

6. The method of claim 1, further comprising:
vectorizing the behavioral source code.

7. The method of claim 6, further comprising:
pre-processing and parallelizing the behavioral source code to prepare the behavioral source code for vectorization.

8. An apparatus comprising:
at least one processor configured to:
obtain behavioral source code defining logic to be performed using at least one logic device, hardware information associated with the at least one logic device, and constraints identifying user requirements associated with the at least one logic device; and
generate a design for the at least one logic device using the behavioral source code, the hardware information, and the constraints such that the design enables the at least one logic device to execute the logic while satisfying the user requirements;
wherein, to generate the design for the at least one logic device, the at least one processor is configured to use a machine learning/artificial intelligence (ML/AI) algorithm that is configured to iteratively modify potential designs to meet the user requirements.

9. The apparatus of claim 8, wherein the ML/AI algorithm is configured to iteratively:
determine whether a current design for the at least one logic device satisfies the user requirements; and
if not, select at least one mitigation and apply the at least one mitigation to the current design for the at least one logic device in order to generate a new design for the at least one logic device.

10. The apparatus of claim 9, wherein:
the at least one mitigation comprises at least one solution method; and
the at least one processor is configured to select the at least one solution method based on knowledge of how the at least one solution method affects the design for the at least one logic device relative to at least one of the user requirements.

11. The apparatus of claim 10, wherein the at least one processor is configured to select the at least one solution method from among multiple solution methods based on a difference between (i) an actual value of a characteristic of the current design for the at least one logic device and (ii) a required value of the characteristic as specified by at least one of the user requirements.

12. The apparatus of claim 8, wherein the user requirements comprise latency, resource, power, and clock frequency requirements.

13. The apparatus of claim 8, wherein the at least one processor is further configured to vectorize the behavioral source code.

14. The apparatus of claim 13, wherein the at least one processor is further configured to pre-process and parallelize the behavioral source code to prepare the behavioral source code for vectorization.

15. A non-transitory computer readable medium containing instructions that when executed cause at least one processor to:
obtain behavioral source code defining logic to be performed using at least one logic device, hardware information associated with the at least one logic device, and constraints identifying user requirements associated with the at least one logic device; and
generate a design for the at least one logic device using the behavioral source code, the hardware information, and the constraints, the design enabling the at least one logic device to execute the logic while satisfying the user requirements;
wherein the instructions that when executed cause the at least one processor to generate the design for the at least one logic device comprise:
instructions that when executed cause the at least one processor to use a machine learning/artificial intelligence (ML/AI) algorithm that is configured to iteratively modify potential designs to meet the user requirements.

16. The non-transitory computer readable medium of claim 15, wherein the ML/AI algorithm is configured to iteratively:
determine whether a current design for the at least one logic device satisfies the user requirements; and
if not, select at least one mitigation and apply the at least one mitigation to the current design for the at least one logic device in order to generate a new design for the at least one logic device.

17. The non-transitory computer readable medium of claim 16, wherein:
the at least one mitigation comprises at least one solution method; and
the instructions when executed further cause the at least one processor to select the at least one solution method based on knowledge of how the at least one solution method affects the design for the at least one logic device relative to at least one of the user requirements.

18. The non-transitory computer readable medium of claim 17, wherein the instructions when executed cause the at least one processor to select the at least one solution method from among multiple solution methods based on a difference between (i) an actual value of a characteristic of the current design for the at least one logic device and (ii) a required value of the characteristic as specified by at least one of the user requirements.

19. The non-transitory computer readable medium of claim 15, wherein the user requirements comprise latency, resource, power, and clock frequency requirements.

20. The non-transitory computer readable medium of claim 15, wherein the instructions when executed further cause the at least one processor to at least one of:
vectorize the behavioral source code; and
pre-process and parallelize the behavioral source code to prepare the behavioral source code for vectorization.
